(19) United States
(12) Patent Application Publication
(10) Pub. No.: US 2025/0105842 A1
(43) Pub. Date: Mar. 27, 2025

(54) CAPACITIVE SWITCH DEVICE

(71) Applicant: Chunghui KANG, Taipei City (TW)

(72) Inventors: Chunghui KANG, Taipei City (TW); Chihkuo CHUI, Taoyuan City (TW); Jui-Ling LEE, New Taipei City (TW)

(21) Appl. No.: 18/808,075

(22) Filed: Aug. 18, 2024

(30) Foreign Application Priority Data
Sep. 22, 2023 (TW) 112136376

(51) Int. Cl. H03K 17/975

(52) U.S. Cl. CPC H03K 17/975

(57) ABSTRACT

A capacitive switch device includes a lower cover, an upper cover, a sliding body, an elastic body, a first conductive part, and a second conductive part. The upper cover is disposed on the lower cover. The sliding body passes through the upper cover and is configured to slide relative to the lower cover along a first direction. The elastic body is located between the lower cover and the upper cover. Two ends of the elastic body respectively abut against the sliding body and the lower cover. The second conductive part is connected to the sliding body and moves relative to the first conductive part. The sliding body drives the second conductive part to move to generate a switch signal corresponding to a capacitance between the first conductive part and the second conductive part.

### CROSS-REFERENCE TO RELATED APPLICATION

This application claims priority to Taiwan Application Serial Number 112136376, filed Sep. 22, 2023, which is herein incorporated by reference in its entirety.

### BACKGROUND

### Field of Invention

The present invention relates to a capacitive switch device.

### Description of Related Art

The keys of the keyboard can be composed of Hall inductive switches, optical switches or mechanical switches. However, the mechanical switches cannot provide switch signals for other states between a pressed state and an unpressed state.

Therefore, how to propose a capacitive switch device that can improve the aforementioned problem is one of the problems that the industry urgently wants to invest in research and development resources to solve.

### SUMMARY

In view of this, one purpose of the present disclosure is to provide a capacitive switch device that can solve the aforementioned problems.

In order to achieve the above objective, in accordance with an embodiment of the present disclosure, a capacitive switch device includes a lower cover, an upper cover, a sliding body, an elastic body, a first conductive part, and a second conductive part. The lower cover is disposed on a circuit board. The upper cover is disposed on the lower cover. The sliding body passes through the upper cover and is configured to slide relative to the lower cover along a first direction. The elastic body is located between the lower cover and the upper cover. Two ends of the elastic body respectively abut against the sliding body and the lower cover. The first conductive part is disposed on the circuit board and is static relative to the lower cover. The second conductive part is connected to the sliding body and moves relative to the first conductive part. The sliding body drives the second conductive part to move along the first direction to generate a switch signal corresponding to a capacitance between the first conductive part and the second conductive part. The switch signal is related to an overlapping area of the first conductive part and the second conductive part in a second direction.

In one or more embodiments of the present disclosure, the first conductive part further includes a first fixed plate disposed on the circuit board, a first conductive narrow plate bent from the first fixed plate, and a first conductive wide plate parallelly extended from the first conductive narrow plate. The second conductive part further includes a second fixed plate connected to the sliding body and a second conductive plate vertically extended from the second fixed plate. The overlapping area of the first conductive part and the second conductive part in the second direction is defined by the first conductive narrow plate, the first conductive wide plate, and the second conductive plate.

In one or more embodiments of the present disclosure, a non-zero distance is between the first conductive narrow plate and the second conductive plate and between the first conductive wide plate and the second conductive plate.

In one or more embodiments of the present disclosure, the first conductive part further includes a first fixed plate passing through the lower cover and two first conductive sub-plates connected to the first fixed plate. The second conductive part further includes a second fixed plate connected to the sliding body and two second conductive sub-plates connected to the second fixed plate. The overlapping area of the first conductive part and the second conductive part in the second direction is defined by the two first conductive sub-plates and the two second conductive sub-plates.

In one or more embodiments of the present disclosure, one of the two first conductive sub-plates is located between the two second conductive sub-plates. One of the two second conductive sub-plates is located between the two first conductive sub-plates.

In order to achieve the above objective, in accordance with an embodiment of the present disclosure, a capacitive switch device includes a lower cover, an upper cover, a sliding body, an elastic body, a first conductive part, and a second conductive part. The lower cover is disposed on the circuit board. The upper cover is disposed on the lower cover. The sliding body passes through the upper cover and is configured to slide relative to the lower cover along the first direction. The elastic body is located between the lower cover and the upper cover. Two ends of the elastic body respectively abut against the sliding body and the lower cover. The first conductive part is disposed on the circuit board and is static relative to the lower cover. The second conductive part is connected to the elastic body and moves relative to the first conductive part. The sliding body drives the second conductive part to move by the elastic body to generate a switch signal corresponding to a capacitance between the first conductive part and the second conductive part. The switch signal is related to a distance between the first conductive part and the second conductive part in a second direction.

In one or more embodiments of the present disclosure, the first conductive part further includes a first fixed plate disposed on the circuit board and a first conductive plate parallelly extended from the first fixed plate. The second conductive part further includes a second swinging plate abutted against by the elastic body and a second conductive plate bent from the second swinging plate.

In one or more embodiments of the present disclosure, the capacitive switch device further includes a spacer located between the first conductive plate and the second conductive plate and disposed on the second conductive plate. The first conductive plate is separated from the second conductive plate by a non-zero distance by the spacer.

In one or more embodiments of the present disclosure, the second swinging plate is abutted against by the elastic body and swings when the sliding body drives the second conductive part to move by the elastic body, so that the second conductive plate moves toward the first conductive plate.

In one or more embodiments of the present disclosure, the capacitive switch device further includes a flexible body located between the first conductive part and the second conductive part. The flexible body abuts against the second conductive part so that a non-zero distance is between the second conductive part and the first conductive part. The second conductive part is located over the first conductive part. The flexible body passes through the first conductive part. The first direction is parallel to the second conductive part.

In order to achieve the above objective, in accordance with an embodiment of the present disclosure, a capacitive switch device includes a lower cover, an upper cover, a sliding body, an elastic body, a first conductive part, and a second conductive part. The lower cover is disposed on the circuit board. The upper cover is disposed on the lower cover. The sliding body passes through the upper cover and is configured to slide relative to the lower cover along the first direction. The elastic body is located between the lower cover and the upper cover. Two ends of the elastic body respectively abut against the sliding body and the lower cover. The first conductive part is disposed on the circuit board and is static relative to the lower cover. The second conductive part is disposed on the circuit board and is separated from the first conductive part. The sliding body drives the elastic body to elastically stretch and compress along the first direction to generate a switch signal corresponding to a capacitance between the first conductive part and the second conductive part. The switch signal is related to a dielectric constant between the first conductive part and the second conductive part.

In one or more embodiments of the present disclosure, a trench is between the first conductive part and the second conductive part. The first conductive part is separated from the second conductive part by the trench.

In one or more embodiments of the present disclosure, the capacitive switch device further includes an insulating layer covering the first conductive part and the second conductive part. When the elastic body is separated from the first conductive part and the second conductive part by the insulating layer when the elastic body is compressed.

In one or more embodiments of the present disclosure, the capacitive switch device further includes a dielectric flexible body disposed on the lower cover. The lower cover has a first opening exposing the trench, the first conductive part, and the second conductive part. The first opening is located on a bottom portion of the lower cover. The lower cover further has a second opening located over the first opening and communicating with the first opening. The first opening is located in a range of the second opening.

In one or more embodiments of the present disclosure, the lower cover has an abutting surface connected between the first opening and the second opening. An edge of the dielectric flexible body abuts against the abutting surface.

In one or more embodiments of the present disclosure, an end of the elastic body abuts against the lower cover by abutting against the dielectric flexible body.

In one or more embodiments of the present disclosure, the dielectric flexible body includes a material with high dielectric constant.

In one or more embodiments of the present disclosure, when the elastic body is separated from the first conductive part and the second conductive part by the dielectric flexible body when the elastic body is compressed and approaches the first conductive part and the second conductive part.

In summary, in the capacitive switch device of the present disclosure, since the sliding body slides relative to the lower cover in a third direction by the elastic body, the user can repeatedly press the capacitive switch device serving as a keyboard key. In the capacitive switch device of the present disclosure, since the first conductive part is fixed on the circuit board and is static relative to the lower cover, and the second conductive part moves relative to the first conductive part as the sliding body slides, so that a capacitance will be generated between the second conductive part and the first conductive part when the second conductive part moves relative to the first conductive part. In the capacitive switch device of the present disclosure, when the second conductive part moves relative to the first conductive part, the capacitance value between the second conductive part and the first conductive part will alter with the change of the overlapping area between the second conductive part and the first conductive part and the change of the distance between the second conductive part and the first conductive part, so that when the user presses the capacitive switch device, the switch signal related to the overlapping area of the second conductive part and the first conductive part or the distance between the second conductive part and the first conductive part can be generated. In the capacitive switch device of the present disclosure, when the first conductive part and the second conductive part are fixed on the circuit board, the user can control the dielectric constant of a medium between the first conductive part and the second conductive part to generate a variation of the capacitance, so that when the user presses the capacitive switch device, the switch signal related to the dielectric constant of the medium between the first conductive part and the second conductive part can be generated. Accordingly, the capacitive switch device of the present disclosure can generate switch signals between the pressed state and the unpressed state, compared with the traditional mechanical switch that can only generate all-or-nothing switch signals between the pressed state and the unpressed state, thereby increasing the flexibility and possibilities of keyboard keys in the field of e-sports.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is an explodes view of a capacitive switch device in accordance with an embodiment of the present disclosure;

FIG. 2 is a perspective cross-sectional view of the capacitive switch device in accordance with an embodiment of the present disclosure;

FIG. 3 is a cross-sectional view of the capacitive switch device in an unpressed state in accordance with an embodiment of the present disclosure;

FIG. 4 is a cross-sectional view of the capacitive switch device in a pressed state in accordance with an embodiment of the present disclosure;

FIG. 5 is an exploded view of the capacitive switch device in accordance with an embodiment of the present disclosure;

FIG. 6 is a perspective cross-sectional view of the capacitive switch device in accordance with an embodiment of the present disclosure;

FIG. 7 is a cross-sectional view of the capacitive switch device in the unpressed state in accordance with an embodiment of the present disclosure;

FIG. 8 is a cross-sectional view of the capacitive switch device in the pressed state in accordance with an embodiment of the present disclosure;

FIG. 9 is an exploded view of the capacitive switch device in accordance with an embodiment of the present disclosure;

FIG. 10 is a perspective cross-sectional view of the capacitive switch device in accordance with an embodiment of the present disclosure;

FIG. 11 is a cross-sectional view of the capacitive switch device in the unpressed state in accordance with an embodiment of the present disclosure;

FIG. 12 is a cross-sectional view of the capacitive switch device in the pressed state in accordance with an embodiment of the present disclosure;

FIG. 13 is an exploded view of the capacitive switch device in accordance with an embodiment of the present disclosure;

FIG. 14 is a perspective cross-sectional view of the capacitive switch device in accordance with an embodiment of the present disclosure;

FIG. 15 is a cross-sectional view of the capacitive switch device in the unpressed state in accordance with an embodiment of the present disclosure;

FIG. 16 is a cross-sectional view of the capacitive switch device in the pressed state in accordance with an embodiment of the present disclosure;

FIG. 17 is an exploded view of the capacitive switch device in accordance with an embodiment of the present disclosure;

FIG. 18 is a perspective cross-sectional view of the capacitive switch device in accordance with an embodiment of the present disclosure;

FIG. 19 is a cross-sectional view of the capacitive switch device in the unpressed state in accordance with an embodiment of the present disclosure;

FIG. 20 is a partial enlarged view of the capacitive switch device in the unpressed state based on FIG. 19 in accordance with an embodiment of the present disclosure;

FIG. 21 is a cross-sectional view of the capacitive switch device in the pressed state in accordance with an embodiment of the present disclosure;

FIG. 22 is a partial enlarged view of the capacitive switch device in the pressed state based on FIG. 21 in accordance with an embodiment of the present disclosure;

FIG. 23 is an exploded view of the capacitive switch device in accordance with an embodiment of the present disclosure;

FIG. 24 is a perspective cross-sectional view of the capacitive switch device in accordance with an embodiment of the present disclosure;

FIG. 25 is a cross-sectional view of the capacitive switch device in the unpressed state in accordance with an embodiment of the present disclosure;

FIG. 26 is a partial enlarged view of the capacitive switch device in the unpressed state based on FIG. 25 in accordance with an embodiment of the present disclosure;

FIG. 27 is a cross-sectional view of the capacitive switch device in the pressed state in accordance with an embodiment of the present disclosure; and

FIG. 28 is a partial enlarged view of the capacitive switch device in the pressed state based on FIG. 27 in accordance with an embodiment of the present disclosure.

### DETAILED DESCRIPTION

Hereinafter, a plurality of embodiments of the present disclosure will be disclosed in diagrams. For the sake of clarity, many details in practice will be described in the following description. However, it should be understood that these details in practice should not limit present disclosure. In other words, in some embodiments of present disclosure, these details in practice are unnecessary. In addition, for simplicity of the drawings, some conventionally used structures and elements will be shown in a simple schematic manner in the drawings. The same reference numbers are used in the drawings and the description to refer to the same or like parts.

Hereinafter, the structure and function of each component included in a capacitive switch device 100 of this embodiment and the connection relationship between the components will be described in detail.

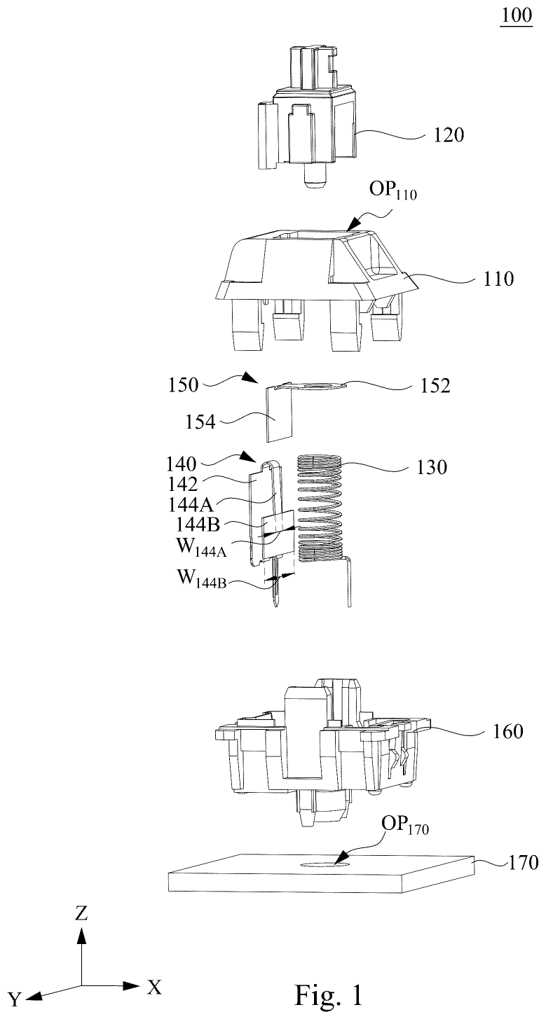

Reference is made to FIG. 1. FIG. 1 is an exploded view of a capacitive switch device 100 in accordance with an embodiment of the present disclosure. As shown in FIG. 1, in this embodiment, the capacitive switch device 100 includes an upper cover 110, a sliding body 120, an elastic body 130, a first conductive part 140, a second conductive part 150, a lower cover 160, and a circuit board 170. The upper cover 110, the sliding body 120, the elastic body 130, the first conductive part 140, the second conductive part 150, the lower cover 160, and the circuit board 170 are generally arranged in a top-down direction. In this embodiment, the upper cover 110 has an opening OP₁₁₀, and the sliding body 120 passes through the upper cover 110 by the opening OP₁₁₀. The elastic body 130 is located between the upper cover 110 and the lower cover 160. The first conductive part 140 further includes a first fixed plate 142, a first conductive narrow plate 144A, and a first conductive wide plate 144B. The first conductive narrow plate 144A is bent from the first fixed plate 142. The first conductive wide plate 144B is parallelly extended from the first conductive narrow plate 144A. In some embodiments, the first conductive narrow plate 144A and the first conductive wide plate 144B are parallel to the first fixed plate 142. The second conductive part 150 further includes a second fixed plate 152 and a second conductive plate 154. The second conductive plate 154 is vertically extended from the second fixed plate 152. The lower cover 160 is combined with the circuit board 170. In some embodiments, the first conductive narrow plate 144A and the first conductive wide plate 144B are parallel to the second conductive plate 154. The circuit board 170 has an opening OP₁₇₀, and a part of the lower cover 160 is combined with the circuit board 170 by the opening OP₁₇₀.

As shown in FIG. 1, in some embodiments, the first fixed plate 142, the composite of the first conductive narrow plate 144A and the first conductive wide plate 144B, and the second conductive plate 154 extend parallel to each other and are arranged in a first direction (e.g., x-direction).

As shown in FIG. 1, in some embodiments, the first conductive narrow plate 144A has a width W_{144A} in the second direction (e.g., y-direction), and the first conductive wide plate 144B has a width W_{144A} in the second direction (e.g., y-direction). In some embodiments, the first conductive narrow plate 144A is located over the first conductive wide plate 144B, and the width W_{144A} of the first conductive narrow plate 144A is less than the width W_{144B} of the first conductive wide plate 144B.

In some other embodiments, the width W_{144A} of the first conductive narrow plate 144A may gradually become greater in a direction toward the first conductive wide plate 144B, and the width W_{144A} of the first conductive narrow plate 144A at an end connected to the first conductive wide plate 144B is substantially equal to the width W_{144B} of the first conductive wide plate 144B. Alternatively, in some other embodiments, the width W_{144A} of the first conductive narrow plate 144A may gradually become greater along a direction toward the first conductive wide plate 144B, and the width W_{144B} of the first conductive wide plate 144B may gradually become greater along a direction away from the first conductive narrow plate 144A, so that the first conductive narrow plate 144A and the first conductive wide plate 144B form a generally triangular shape.

In some embodiments, the capacitive switch device 100 is configured as a key of a keyboard and is configured to generate a switch signal corresponding to an unpressed state and a pressed state.

In some embodiments, the sliding body 120 is configured to be pressed by a user.

In some embodiments, the materials of the upper cover 110, the sliding body 120, and the lower cover 160 may include, for example, plastic or other suitable insulating materials.

In some embodiments, the materials of the elastic body 130, the first conductive part 140, and the second conductive part 150 may include, for example, metal or other suitable conductive materials.

In some embodiments, the elastic body 130 may be, for example, a spring or other suitable elastic material.

In some embodiments, the circuit board 170 may be, for example, a printed circuit board (PCB).

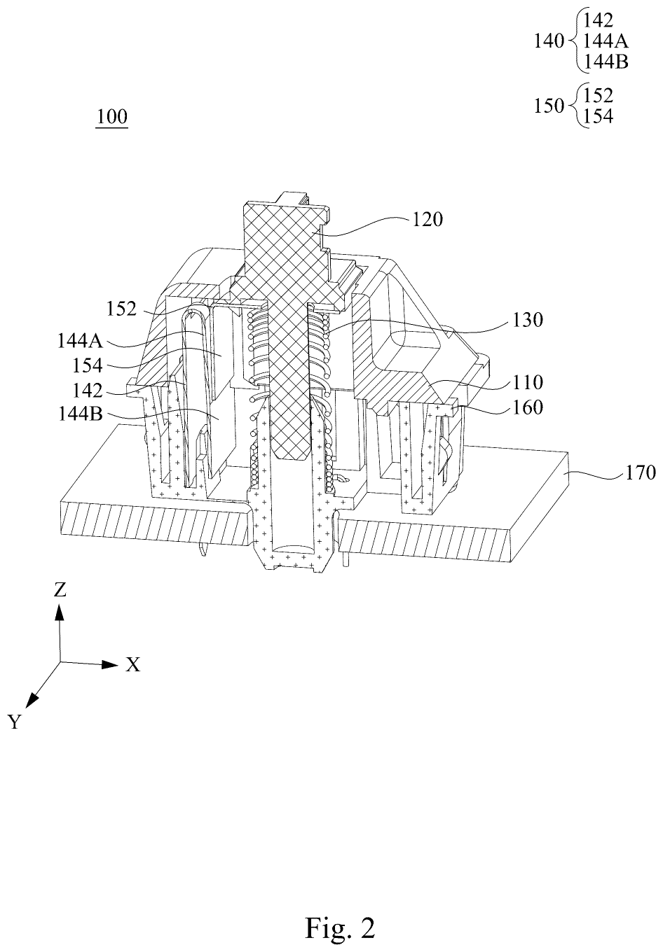

Reference is made to FIG. 2. FIG. 2 is a perspective cross-sectional view of the capacitive switch device 100 in accordance with an embodiment of the present disclosure. As shown in FIG. 2, in this embodiment, the lower cover 160 is disposed on the circuit board 170. Specifically, the circuit board 170 has the opening OP₁₇₀, and a part of the lower cover 160 is combined with the circuit board 170 by the opening OP₁₇₀. The upper cover 110 is disposed on the lower cover 160. Specifically, the upper cover 110 is combined with the lower cover 160 (for example, locked with each other) and form an accommodating space. The sliding body 120 passes through the upper cover 110 and is configured to slide relative to the lower cover 160 along a third direction (e.g., z-direction). In some embodiments, a part of the sliding body 120 is formed as a positioning shaft, and a part of the lower cover 160 is formed as a positioning trench. The sliding body 120 slides relative to the lower cover 160 through the structure of the positioning shaft and the positioning trench. The elastic body 130 is located in the aforementioned accommodating space formed by the upper cover 110 and the lower cover 160, and two ends of the elastic body 130 respectively abut against the sliding body 120 and the lower cover 160. In some embodiments, the elastic body 130 is sleeved on the positioning shaft of the sliding body 120 and the positioning trench of the lower cover 160. The first conductive part 140 is disposed on the circuit board 170 and is static relative to the lower cover 160. The second conductive part 150 is connected to the sliding body 120 and moves relative to the first conductive part 140. The sliding body 120 drives the second conductive part 150 to move along the third direction (e.g., z-direction) to generate a switch signal corresponding to a capacitance value. The aforementioned capacitance value corresponds to a capacitance formed between the first conductive part 140 and the second conductive part 150.

How the capacitive switch device 100 generates the switch signal will be described in detail below.

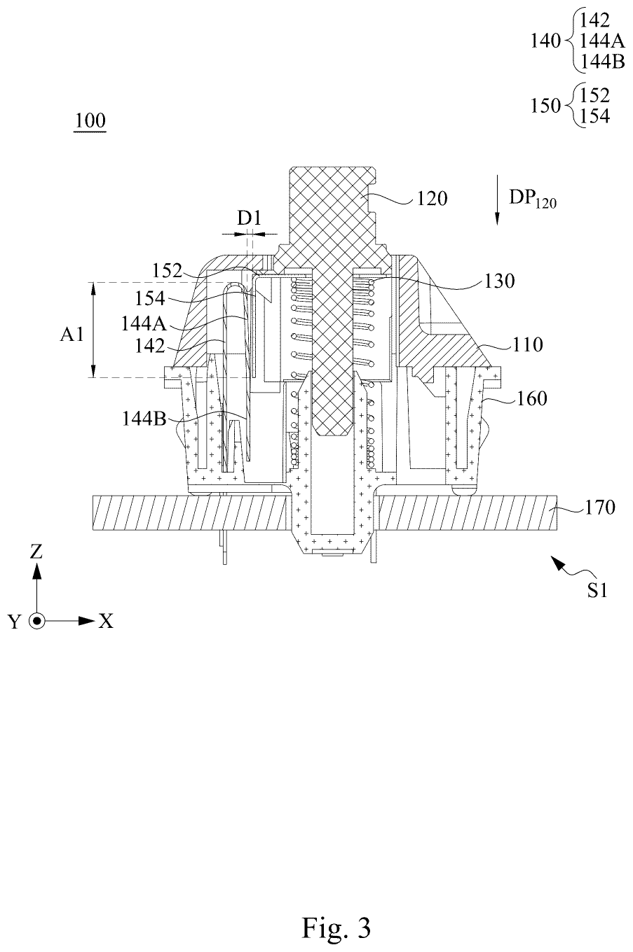

Reference is made to FIG. 3. FIG. 3 is a cross-sectional view of the capacitive switch device 100 in an unpressed state S1 in accordance with an embodiment of the present disclosure. As shown in FIG. 3, in this embodiment, the sliding body 120 of the capacitive switch device 100 is configured to allow the user to press along a pressing direction DP₁₂₀. When the capacitive switch device 100 is in the unpressed state S1, the second conductive plate 154 is adjacent to the first conductive narrow plate 144A. As shown in FIG. 3, there is a distance D1 between the second conductive plate 154 and the first conductive narrow plate 144A. In detail, the distance D1 is a shortest distance between the second conductive plate 154 and the first conductive narrow plate 144A. As shown in FIG. 3, the second conductive plate 154 and the first conductive narrow plate 144A have an overlapping area A1 in the first direction (e.g., x-direction).

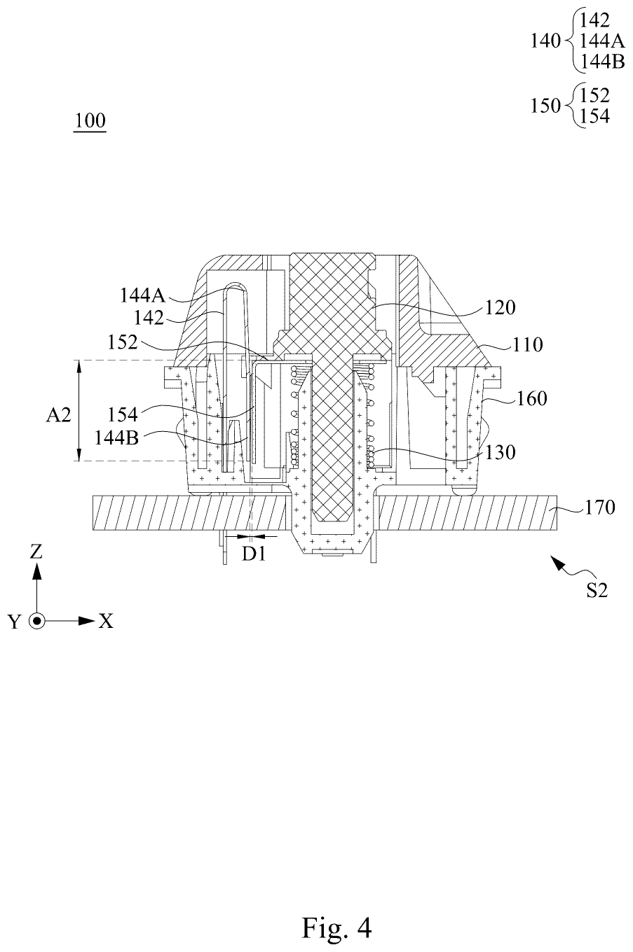

Reference is made to FIG. 4. FIG. 4 is a cross-sectional view of the capacitive switch device 100 in a pressed state S2 in accordance with an embodiment of the present disclosure. As shown in FIG. 4, in this embodiment, when the capacitive switch device 100 is in the pressing state S2, the sliding body 120 drives the second conductive plate 154 of the second conductive part 150 to move downward along the pressing direction DP₁₂₀, so that the second conductive plate 154 is adjacent to the first conductive wide plate 144B. As shown in FIG. 4, there is a distance D1 between the second conductive plate 154 and the first conductive wide plate 144B. In some embodiments, the distance D1 in the pressed state S2 is the same as the distance D1 in the unpressed state S1. In some other embodiments, the distance D1 in the pressed state S2 is less than the distance D1 in the unpressed state S1. Regardless of whether the distance D1 in the pressed state S2 is the same as the distance D1 in the unpressed state S1, the distance D1 must be a non-zero distance (i.e., the first conductive part 140 and the second conductive part 150 are not in contact). As shown in FIG. 4, the second conductive plate 154 and the first conductive wide plate 144B have an overlapping area A2 in the first direction (e.g., x-direction).

In some other embodiments, an insulating material may be coated on surfaces of the first conductive part 140 and the second conductive part 150. This can prevent the first conductive part 140 and the second conductive part 150 from being too close during the pressing process, which may cause the capacitive effect between the first conductive part 140 and the second conductive part 150 to fail. It should be noted that the first conductive part 140 and the second conductive part 150 are “in contact with each other” if the insulating material and the first conductive part 140 are regarded as one and the insulating material and the second conductive part 150 are regarded as one as well. Otherwise, the first conductive part 140 and the second conductive part 150 are separated by the insulating material and “do not in contact with each other” if the insulating material is regarded as an independent element from the first conductive part 140 and the second conductive part 150. Therefore, the two literal interpretations “the first conductive part 140 and the second conductive part 150 are in contact with each other” and “the first conductive part 140 and the second conductive part 150 are not in contact with each other” should be regarded as equivalent.

Reference is made to FIG. 1, FIG. 3, and FIG. 4. By the aforementioned structural configuration, when the capacitive switch device 100 continuously changes between the unpressed state S1 and the pressed state S2, the capacitive switch device 100 can generate a switch signal between the unpressed state S1 and the pressed state S2. In detail, when the capacitive switch device 100 is in the unpressed state S1, there is a relatively less overlapping area A1 between the second conductive plate 154 and the first conductive narrow plate 144A, resulting in a relatively less capacitance. However, when the capacitive switch device 100 is in the pressed state S2, there is a relatively greater overlapping area A2 between the second conductive plate 154 and the first conductive wide plate 144B, resulting in a relatively greater capacitance. Since the capacitance value is positively correlated with the overlapping area, the capacitive switch device 100 can generate the switch signal related to the overlapping area of the first conductive part 140 and the second conductive part 150 in the first direction (e.g., x-direction).

Hereinafter, the structure and function of each component included in a capacitive switch device 200 of this embodiment and the connection relationship between the components will be described in detail.

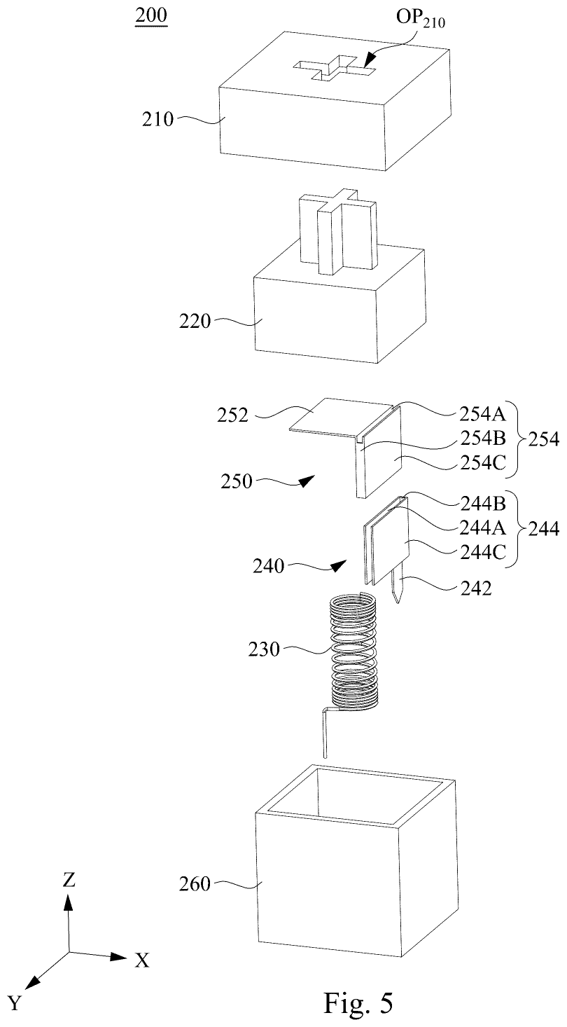

Reference is made to FIG. 5. FIG. 5 is an exploded view of a capacitive switch device 200 in accordance with an embodiment of the present disclosure. As shown in FIG. 5, in this embodiment, the capacitive switch device 200 includes an upper cover 210, a sliding body 220, an elastic body 230, a first conductive part 240, a second conductive part 250, and a lower cover 260. In this embodiment, the capacitive switch device 200 substantially also includes a circuit board. However, for simplicity, the relevant technical features of the circuit board will not be described again herein. The upper cover 210, the sliding body 220, the elastic body 230, the first conductive part 240, the second conductive part 250, and the lower cover 260 are generally arranged in a top-down direction. In this embodiment, the upper cover 210 has an opening OP₂₁₀ that matches the shape of the sliding body 220, and the sliding body 220 passes through the upper cover 210 by the opening OP₂₁₀. The elastic body 230 is located between the upper cover 210 and the lower cover 260.

As shown in FIG. 5, in this embodiment, the first conductive part 240 further includes a first fixed plate 242 and a first conductive plate 244 connected to the first fixed plate 242. The first conductive plate 244 further includes a first conductive sub-plate 244A, a first connecting plate 244B, and a first conductive sub-plate 244C. The first conductive sub-plate 244A and the first conductive sub-plate 244C are connected to the first fixed plate 242, and the first conductive sub-plate 244A and the first conductive sub-plate 244C are extended in parallel. The second conductive part 250 further includes a second fixed plate 252 and a second conductive plate 254 connected to the second fixed plate 252. The second conductive plate 254 further includes a second conductive sub-plate 254A, a second connecting plate 254B, and a second conductive sub-plate 254C. The second conductive sub-plate 254A and the second conductive sub-plate 254C are connected to the second fixed plate 252, and the second conductive sub-plate 254A and the second conductive sub-plate 254C are extended in parallel.

As shown in FIG. 5, in some embodiments, the first conductive sub-plate 244A, the first conductive sub-plate 244C, the second conductive sub-plate 254A and the second conductive sub-plate 254C are extended in parallel to each other and are arranged in a first direction (e.g., x-direction).

As shown in FIG. 5, in some embodiments, in a top view along the third direction (e.g., z-direction), the composite of the first conductive sub-plate 244A, the first connecting plate 244B, and the first conductive sub-plate 244C presents an inverted U-shape, and the composite of the second conductive sub-plate 254A, the second connecting plate 254B, and the second conductive sub-plate 254C presents an inverted U-shape.

In some embodiments, the materials of the upper cover 210, the sliding body 220, and the lower cover 260 may include, for example, plastic or other suitable insulating materials.

In some embodiments, the materials of the elastic body 230, the first conductive part 240, and the second conductive part 250 may include, for example, metal or other suitable conductive materials.

In some embodiments, the elastic body 230 may be, for example, a spring or other suitable elastic material.

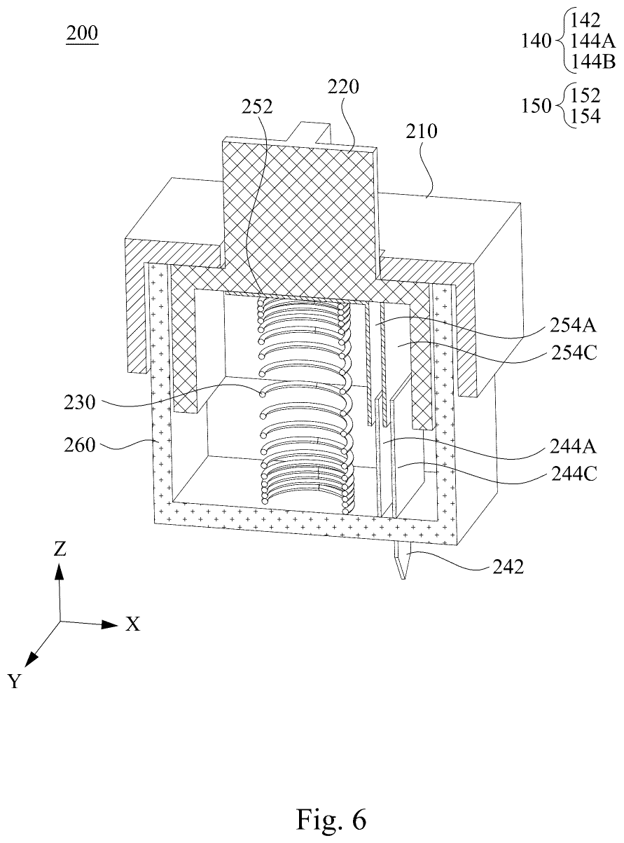

Reference is made to FIG. 6. FIG. 6 is a perspective cross-sectional view of the capacitive switch device 200 in accordance with an embodiment of the present disclosure. As shown in FIG. 6, in this embodiment, the lower cover 260 is disposed on the circuit board. The upper cover 210 is disposed on the lower cover 260. Specifically, the upper cover 210 is combined with the lower cover 260 (for example, locked with each other) and form an accommodating space. The sliding body 220 passes through the upper cover 210 and is configured to slide relative to the lower cover 260 along a third direction (e.g., z-direction). The elastic body 230 is located in the aforementioned accommodating space formed by the upper cover 210 and the lower cover 260, and two ends of the elastic body 230 respectively abut against the sliding body 220 and the lower cover 260. In some embodiments, the two ends of the elastic body 230 respectively abut against the second fixed plate 252 and the lower cover 260. The first conductive part 240 is disposed on the circuit board and is static relative to the lower cover 260. The second conductive part 250 is connected to the sliding body 220 and moves relative to the first conductive part 240. The sliding body 220 drives the second conductive part 250 to move along the third direction (e.g., z-direction) to generate a switch signal corresponding to a capacitance value. The aforementioned capacitance value corresponds to a capacitance formed between the first conductive part 240 and the second conductive part 250.

How the capacitive switch device 200 generates the switch signal will be described in detail below.

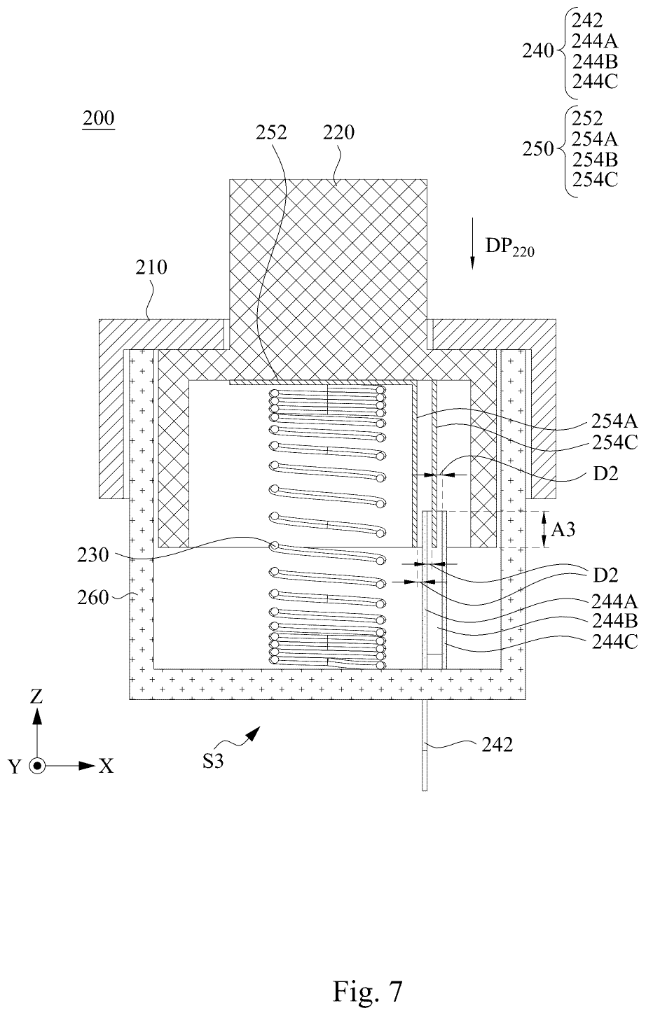

Reference is made to FIG. 7. FIG. 7 is a cross-sectional view of the capacitive switch device 200 in an unpressed state S3 in accordance with an embodiment of the present disclosure. As shown in FIG. 7, in this embodiment, the sliding body 220 of the capacitive switch device 200 is configured to allow the user to press along a pressing direction DP₂₂₀. When the capacitive switch device 200 is in the unpressed state S3, the first conductive sub-plate 244A is located between the second conductive sub-plate 254A and the second conductive sub-plate 254C, and the second conductive sub-plate 254C is located between the first conductive sub-plate 244A and the first conductive sub-plate 244C. As shown in FIG. 7, there is a distance D2 between the second conductive sub-plate 254A and the first conductive sub-plate 244A, there is a distance D2 between the first conductive sub-plate 244A and the second conductive sub-plate 254C, and there is also a distance D2 between the second conductive sub-plate 254C and the first conductive sub-plate 244C. In detail, the distance D2 is a shortest distance between any two adjacent conductive sub-plates mentioned above. As shown in FIG. 7, the first conductive sub-plate 244A, the first conductive sub-plate 244C, the second conductive sub-plate 254A, and the second conductive sub-plate 254C have an overlapping area A3 in the first direction (e.g., x-direction).

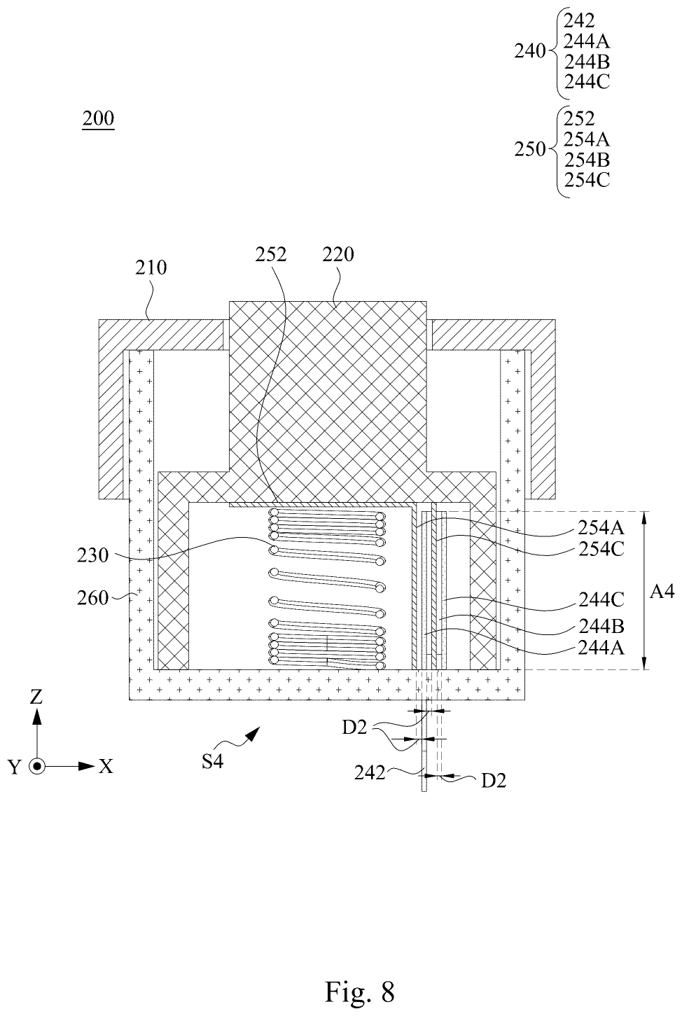

Reference is made to FIG. 8. FIG. 8 is a cross-sectional view of the capacitive switch device 200 in a pressed state S4 in accordance with an embodiment of the present disclosure. As shown in FIG. 8, in this embodiment, when the capacitive switch device 200 is in the pressed state S4, the sliding body 220 drives the second conductive sub-plate 254A and the second conductive sub-plate 254C of the second conductive part 250 to move downward along the pressing direction DP₂₂₀, so that when the second conductive part 250 abuts against the lower cover 260, there is still the distance D2 between the second conductive sub-plate 254A and the first conductive sub-plate 244A, there is still the distance D2 between the first conductive sub-plate 244A and the second conductive sub-plate 254C, and there is still the distance D2 between the second conductive sub-plate 254C and the first conductive sub-plate 244C. In some embodiments, the distance D2 in the pressed state S4 is the same as the distance D2 in the unpressed state S3. Regardless of whether the distance D2 in the pressed state S4 is the same as the distance D2 in the unpressed state S3, the distance D2 must be a non-zero distance (i.e., the first conductive part 240 and the second conductive part 250 are not in contact). As shown in FIG. 8, the first conductive sub-plate 244A, the first conductive sub-plate 244C, the second conductive sub-plate 254A and the second conductive sub-plate 254C have an overlapping area A4 in the first direction (e.g., x-direction).

In some other embodiments, an insulating material may be coated on the surfaces of the first conductive part 240 and the second conductive part 250. This can prevent the first conductive part 240 and the second conductive part 250 from being too close during the pressing process, which may cause the capacitive effect between the first conductive part 240 and the second conductive part 250 to fail. It should be noted that the first conductive part 240 and the second conductive part 250 are “in contact with each other” if the insulating material and the first conductive part 240 are regarded as one and the insulating material and the second conductive part 250 are regarded as one as well. Otherwise, the first conductive part 240 and the second conductive part 250 are separated by the insulating material and “do not in contact with each other” if the insulating material is regarded as an independent element from the first conductive part 240 and the second conductive part 250. Therefore, the two literal interpretations “the first conductive part 240 and the second conductive part 250 are in contact with each other” and “the first conductive part 240 and the second conductive part 250 are not in contact with each other” should be regarded as equivalent.

Reference is made to FIG. 5, FIG. 7, and FIG. 8. By the aforementioned structural configuration, when the capacitive switch device 200 continuously changes between the unpressed state S3 and the pressed state S4, the capacitive switch device 200 can generate a switch signal between the unpressed state S3 and the pressed state S4. In detail, when the capacitive switch device 200 is in the unpressed state S3, there is a relatively less overlapping area A1 among the first conductive sub-plate 244A, the first conductive sub-plate 244C, the second conductive sub-plate 254A, and the second conductive sub-plate 254C, resulting in a relatively less capacitance. However, when the capacitive switch device 200 is in the pressed state S4, there is a relatively greater overlapping area A2 among the first conductive sub-plate 244A, the first conductive sub-plate 244C, the second conductive sub-plate 254A, and the second conductive sub-plate 254C, resulting in a relatively greater capacitance. Since the capacitance value is positively correlated to the aforementioned overlapping area, the capacitive switch device 200 can generate the switch signal related to the overlapping area of the first conductive sub-plate 244A, the first conductive sub-plate 244C, the second conductive sub-plate 254A, and the second conductive sub-plate 254C in the first direction (e.g., x-direction).

Hereinafter, the structure and function of each component included in a capacitive switch device 300 of this embodiment and the connection relationship between the components will be described in detail.

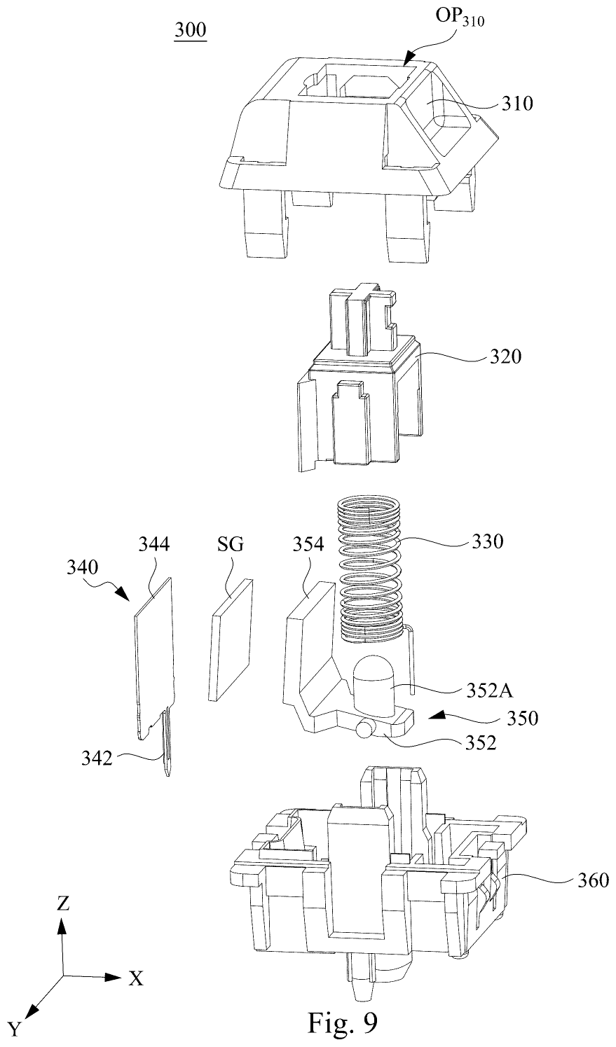

Reference is made to FIG. 9. FIG. 9 is an exploded view of a capacitive switch device 300 in accordance with an embodiment of the present disclosure. As shown in FIG. 9, in this embodiment, the capacitive switch device 300 includes an upper cover 310, a sliding body 320, an elastic body 330, a first conductive part 340, a second conductive part 350, and a lower cover 360. In this embodiment, the capacitive switch device 300 substantially also includes a circuit board. However, for simplicity, the relevant technical features of the circuit board will not be described again herein. The upper cover 310, the sliding body 320, the elastic body 330, the first conductive part 340, the second conductive part 350, and the lower cover 360 are generally arranged in a top-down direction. In this embodiment, the upper cover 310 has an opening OP₃₁₀, and the sliding body 320 passes through the upper cover 310 by the opening OP₃₁₀. The elastic body 330 is located between the upper cover 310 and the lower cover 360.

As shown in FIG. 9, in this embodiment, the first conductive part 340 further includes a first fixed plate 342 and a first conductive plate 344 connected to the first fixed plate 342. The first fixed plate 342 is disposed on the circuit board. The first conductive plate 344 is connected to the first fixed plate 342, and the first conductive plate 344 and the first fixed plate 342 are extended in parallel. The second conductive part 350 further includes a second swinging plate 352, a positioning pillar 352A, and a second conductive plate 354 connected to the second swinging plate 352. The positioning pillar 352A is disposed on the second swinging plate 352. In some embodiments, the second conductive plate 354 is generally vertically extended from the second swinging plate 352.

As shown in FIG. 9, in this embodiment, the capacitive switch device 300 further includes a spacer SG located between the first conductive plate 344 and the second conductive plate 354.

In some embodiments, the materials of the upper cover 310, the sliding body 320, and the lower cover 360 may include, for example, plastic or other suitable insulating materials.

In some embodiments, the materials of the elastic body 330 and the first conductive part 340 may include, for example, metal or other suitable conductive materials.

In some embodiments, the elastic body 330 may be, for example, a spring or other suitable elastic material.

In some embodiments, the material of the second conductive part 350 may include, for example, conductive plastic or other suitable conductive materials.

In some embodiments, the spacer SG may be, for example, sponge, foam or other suitable spacer materials.

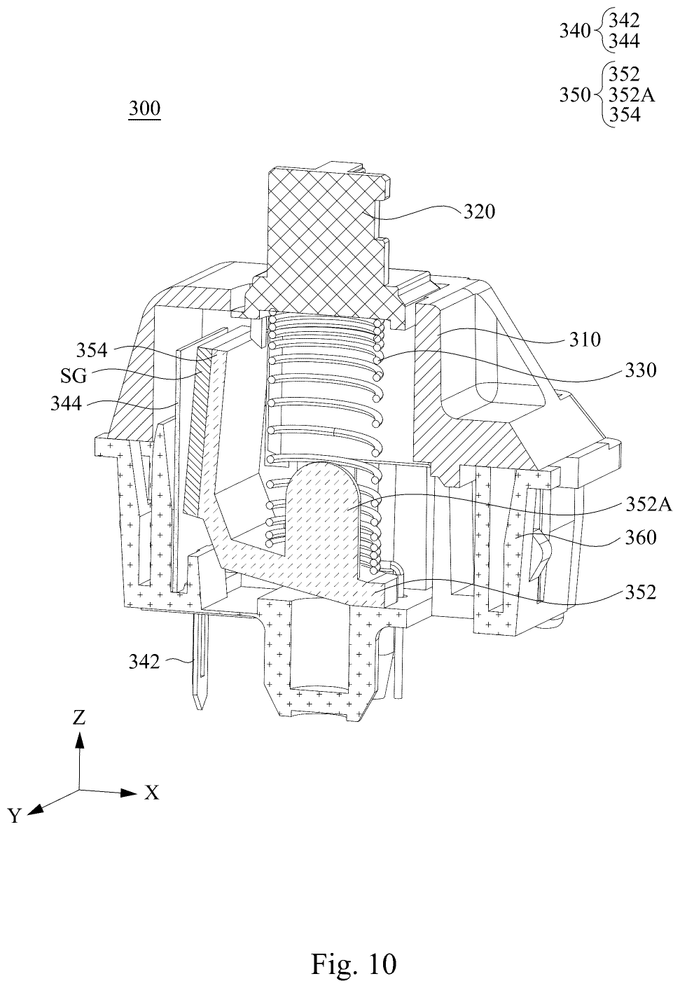

Reference is made to FIG. 10. FIG. 10 is a perspective cross-sectional view of the capacitive switch device 300 in accordance with an embodiment of the present disclosure. As shown in FIG. 10, in this embodiment, the lower cover 360 is disposed on the circuit board. The upper cover 310 is disposed on the lower cover 360. Specifically, the upper cover 310 is combined to the lower cover 360 (for example, locked with each other) and form an accommodating space.

The sliding body 320 passes through the upper cover 310 and is configured to slide relative to the lower cover 360 along a third direction (e.g., z-direction). The elastic body 330 is located in the aforementioned accommodating space formed by the upper cover 310 and the lower cover 360. The elastic body 330 is sleeved on the positioning pillar 352A, and two ends of the elastic body 330 respectively abut against the sliding body 320 and the second swinging plate 352. The first conductive part 340 is disposed on the circuit board and is static relative to the lower cover 360. The second conductive part 350 is connected to the sliding body 320 by the elastic body 330 and moves relative to the first conductive part 340. More specifically, the second conductive part 350 swings relative to the first conductive part 340. In some embodiments, the spacer SG is disposed on the second conductive plate 354. The sliding body 320 drives the second conductive part 350 to rotate relative to a rotation axis along the third direction (for example, z-direction) parallel to the second direction (for example, y-direction) and swings the second conductive plate 354 toward the first conductive plate 344 to generate a switch signal corresponding to a capacitance value. The aforementioned capacitance value corresponds to a capacitance (Capacitance) formed between the first conductive part 340 and the second conductive part 350.

How the capacitive switch device 300 generates the switch signal will be described in detail below.

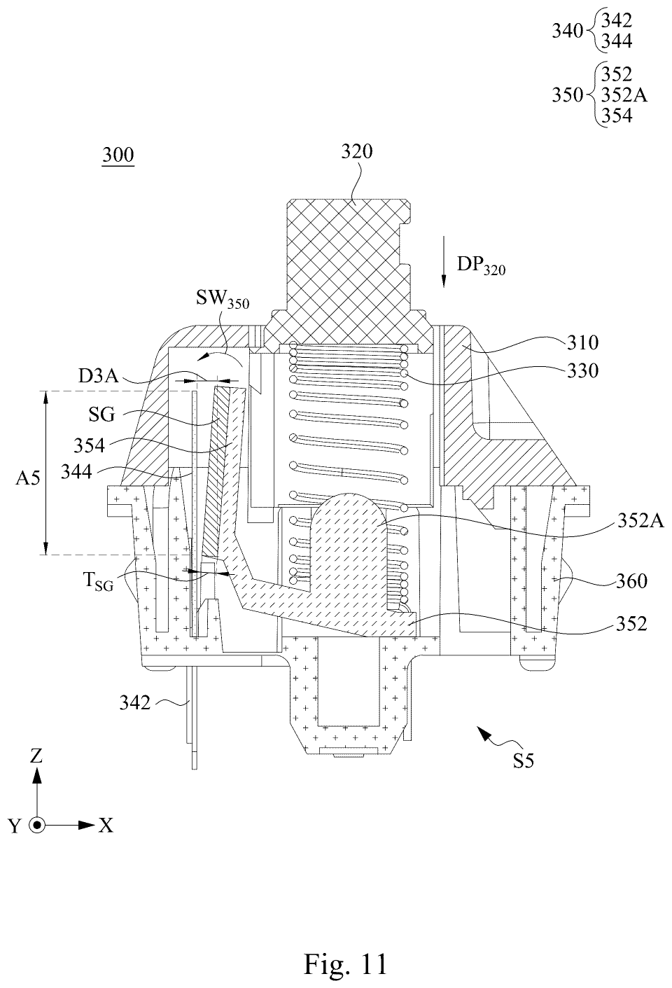

Reference is made to FIG. 11. FIG. 11 is a cross-sectional view of the capacitive switch device 300 in an unpressed state S5 in accordance with an embodiment of the present disclosure. As shown in FIG. 11, in this embodiment, the sliding body 320 of the capacitive switch device 300 is configured to allow the user to press along a pressing direction DP₃₂₀. When the capacitive switch device 300 is in the unpressed state S5, there is a distance D3A between the first conductive plate 344 and the second conductive plate 354. In detail, the distance D3A is a shortest distance between the first conductive plate 344 and the second conductive plate 354. As shown in FIG. 11, the first conductive plate 344 and the second conductive plate 354 have an overlapping area A5 in the first direction (e.g., x-direction). In some embodiments, the spacer SG has a thickness T_{SG}.

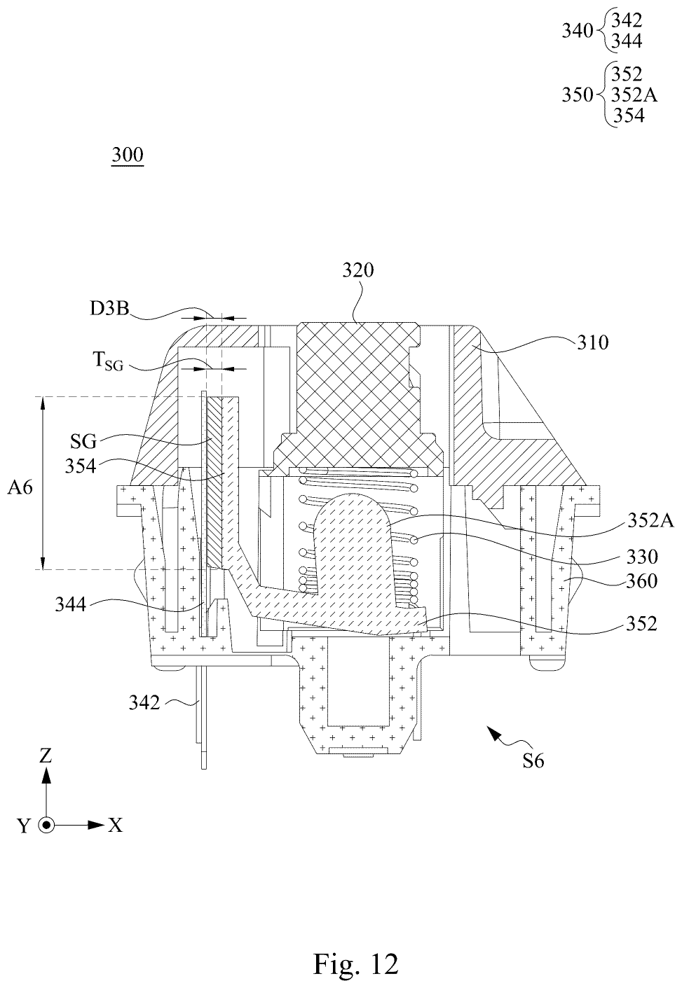

Reference is made to FIG. 12. FIG. 12 is a cross-sectional view of the capacitive switch device 300 in a pressed state S6 in accordance with an embodiment of the present disclosure. As shown in FIG. 12, in this embodiment, when the capacitive switch device 300 is in the pressed state S6, the sliding body 320 drives the second conductive part 350 along the third direction (for example, z-direction) to rotate relative to a rotation axis parallel to the second direction (for example, y-direction) and move toward the first conductive plate 344 along a swinging direction SW₃₅₀ as shown in FIG. 11, so that when the spacer SG abuts against the first conductive part 340, there is a distance D3B between the first conductive plate 344 and the second conductive plate 354. In some embodiments, the distance D3B in the pressed state S6 is substantially equal to the thickness T_{SG} of the spacer SG. In some embodiments, the distance D3B in the pressed state S6 is less than the distance D3A in the unpressed state S5, and the distance D3A and the distance D3B must be non-zero distances (i.e., the first conductive part 340 and the second conductive part 350 are not in contact). More specifically, since the spacer SG is disposed on the second conductive plate 354 and is located between the first conductive plate 344 and the second conductive plate 354, it can be ensured that the first conductive plate 344 and the second conductive plate 354 are not in contact. As shown in FIG. 12, the first conductive plate 344 and the second conductive plate 354 have an overlapping area A6 in the first direction (e.g., x-direction).

In some other embodiments, an insulating material may be coated on surfaces of the first conductive part 340 and the second conductive part 350. This can prevent the first conductive part 340 and the second conductive part 350 from being too close during the pressing process, which may cause the capacitive effect between the first conductive part 340 and the second conductive part 350 to fail. It should be noted that the first conductive part 340 and the second conductive part 350 are “in contact with each other” if the insulating material and the first conductive part 340 are regarded as one and the insulating material and the second conductive part 350 are regarded as one as well. Otherwise, the first conductive part 340 and the second conductive part 350 are separated by the insulating material and “do not in contact with each other” If the insulating material is regarded as an independent element from the first conductive part 340 and the second conductive part 350. Therefore, the two literal interpretations “the first conductive part 340 and the second conductive part 350 are in contact with each other” and “the first conductive part 340 and the second conductive part 350 are not in contact with each other” should be regarded as equivalent.

Reference is made to FIG. 9, FIG. 11, and FIG. 12. By the aforementioned structural configuration, when the capacitive switch device 300 continuously changes between the unpressed state S5 and the pressed state S6, the capacitive switch device 300 can generate a switch signal between the unpressed state S5 and the pressed state S6. In detail, when the capacitive switch device 300 is in the unpressed state S5, there is a relatively greater distance D3A between the first conductive plate 344 and the second conductive plate 354, resulting in a relatively less capacitance. However, when the capacitive switch device 300 is in the pressed state S6, there is a relatively less distance D3B between the first conductive plate 344 and the second conductive plate 354, resulting in a relatively greater capacitance. Since the capacitance value is negatively correlated with the distance, the capacitive switch device 300 can generate the switch signal related to the distance between the first conductive part 340 and the second conductive part 350.

Hereinafter, the structure and function of each component included in a capacitive switch device 400 of this embodiment and the connection relationship between the components will be described in detail.

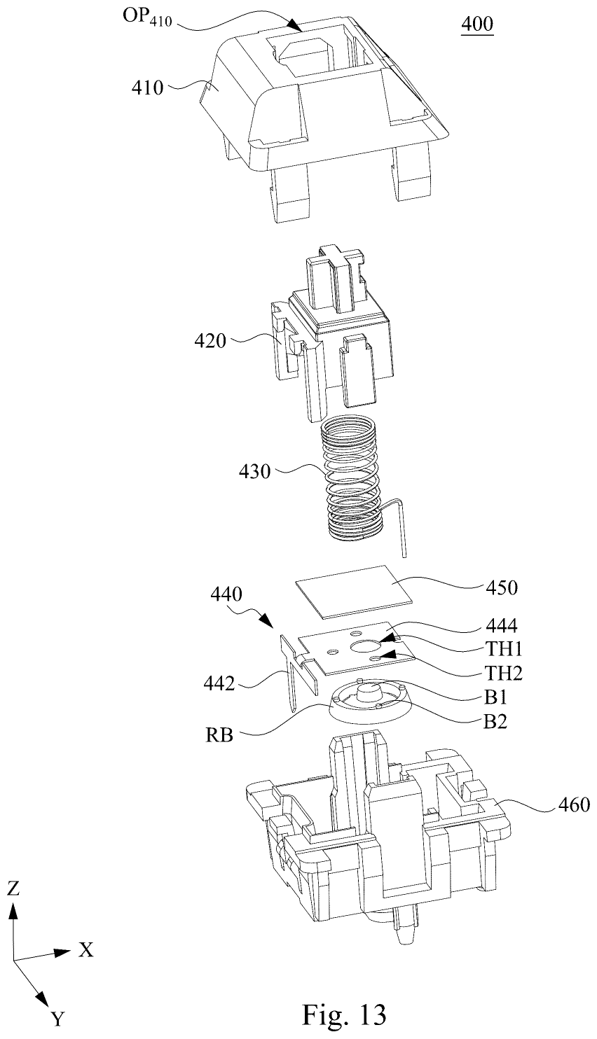

Reference is made to FIG. 13. FIG. 13 is an exploded view of a capacitive switch device 400 in accordance with an embodiment of the present disclosure. As shown in FIG. 13, in this embodiment, the capacitive switch device 400 includes an upper cover 410, a sliding body 420, an elastic body 430, a first conductive part 440, a second conductive part 450, and a lower cover 460. In this embodiment, the capacitive switch device 400 substantially also includes a circuit board. However, for simplicity, the relevant technical features of the circuit board will not be described again herein. The upper cover 410, the sliding body 420, the elastic body 430, the first conductive part 440, the second conductive part 450, and the lower cover 460 are generally arranged in a top-down direction. In this embodiment, the upper cover 410 has an opening OP₄₁₀, and the sliding body 420 passes through the upper cover 410 by the opening OP₄₁₀. The elastic body 430 is located between the upper cover 410 and the lower cover 460.

As shown in FIG. 13, in this embodiment, the first conductive part 440 further includes a first fixed plate 442 and a first conductive plate 444 connected to the first fixed plate 442. The first fixed plate 442 is disposed on the circuit board. The first conductive plate 444 is connected to the first fixed plate 442, and the first conductive plate 444 and the first fixed plate 442 are extended in parallel. The second conductive part 450 and the first conductive plate 444 are extended in parallel.

As shown in FIG. 13, in this embodiment, the capacitive switch device 400 further includes a flexible body RB located between the first conductive part 440 and the second conductive part 450. The flexible body RB is configured to pass through the first conductive part 440. Specifically, the flexible body RB includes a first convex portion B1 and a plurality of second convex portions B2. The first convex portion B1 is located in the center of the flexible body RB, and the second convex portions B2 surround the first convex portion B1. The first conductive plate 444 has a first through hole TH1 and second through holes TH2 respectively corresponding to the first convex portion B1 and the second convex portions B2.

In some embodiments, the materials of the upper cover 410, the sliding body 420, and the lower cover 460 may include, for example, plastic or other suitable insulating materials.

In some embodiments, the materials of the first conductive part 440 and the second conductive part 450 of the elastic body 430 may include, for example, metal or other suitable conductive materials.

In some embodiments, the elastic body 430 may be, for example, a spring or other suitable elastic material.

In some embodiments, the flexible body RB may be, for example, rubber or other suitable flexible materials.

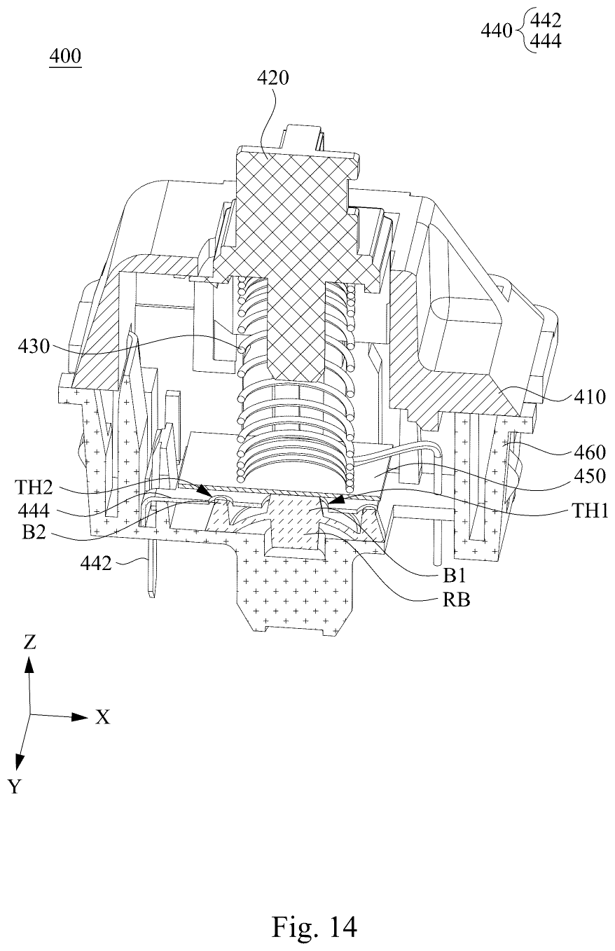

Reference is made to FIG. 14. FIG. 14 is a perspective cross-sectional view of the capacitive switch device 400 in accordance with an embodiment of the present disclosure. As shown in FIG. 14, in this embodiment, the lower cover 460 is disposed on the circuit board. The upper cover 410 is disposed on the lower cover 460. Specifically, the upper cover 410 is combined with the lower cover 460 (for example, locked with each other) and form an accommodating space. The sliding body 420 passes through the upper cover 410 and is configured to slide relative to the lower cover 460 along a third direction (e.g., z-direction). The elastic body 430 is located in the aforementioned accommodating space formed by the upper cover 410 and the lower cover 460. Two ends of the elastic body 430 respectively abut against the sliding body 420 and the second conductive part 450. The first conductive part 440 is disposed on the circuit board and is static relative to the lower cover 460. The second conductive part 450 moves relative to the first conductive part 440 by the elastic body 430. Specifically, the second conductive part 450 moves relative to the first conductive part 440 by the elastic restoring force of the elastic body 430 to abut against the flexible body RB. In some embodiments, the flexible body RB is disposed on the lower cover 460 and is located between the lower cover 460 and the second conductive part 450, and the first convex portion B1 of the flexible body RB abuts against the second conductive part 450. The sliding body 420 drives the second conductive part 450 along the third direction (e.g., z-direction) to move relative to the first conductive part 440 to generate a switch signal corresponding to a capacitance value. The aforementioned capacitance value corresponds to a capacitance formed between the first conductive part 440 and the second conductive part 450.

How the capacitive switch device 400 generates the switch signal will be described in detail below.

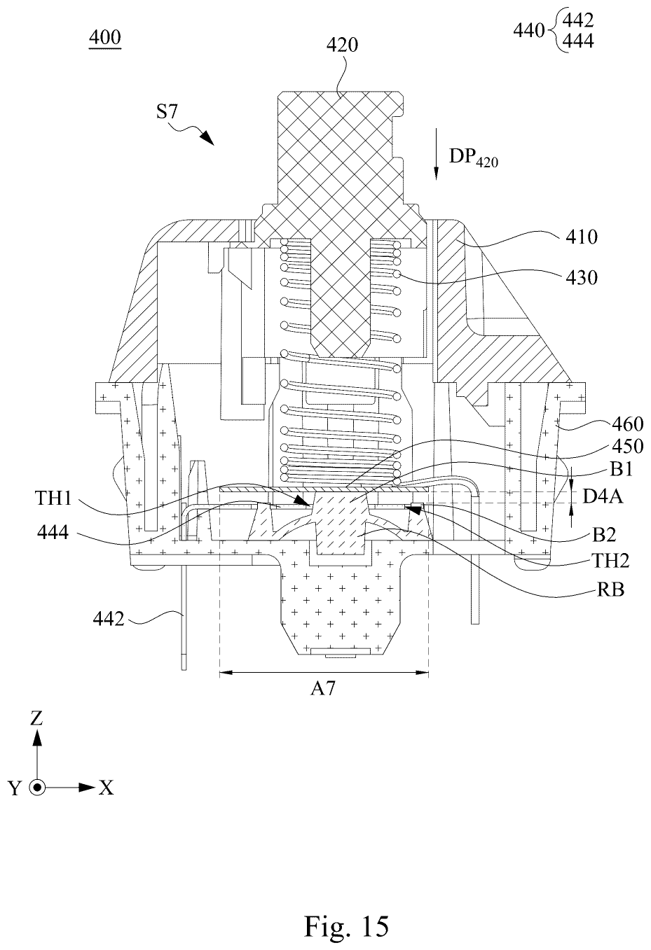

Reference is made to FIG. 15. FIG. 15 is a cross-sectional view of the capacitive switch device 400 in an unpressed state S7 in accordance with an embodiment of the present disclosure. As shown in FIG. 15, in this embodiment, the sliding body 420 of the capacitive switch device 400 is configured to allow the user to press along a pressing direction DP₄₂₀. When the capacitive switch device 400 is in the unpressed state S7, there is a distance D4A between the first conductive plate 444 and the second conductive part 450. In detail, the distance D4A is a shortest distance between the first conductive plate 444 and the second conductive part 450. As shown in FIG. 15, the first conductive plate 444 and the second conductive part 450 have an overlapping area A7 in the third direction (e.g., z-direction). In some embodiments, when the capacitive switch device 400 is in the unpressed state S7, there is a buffer space between the first convex portion B1 and the lower cover 460.

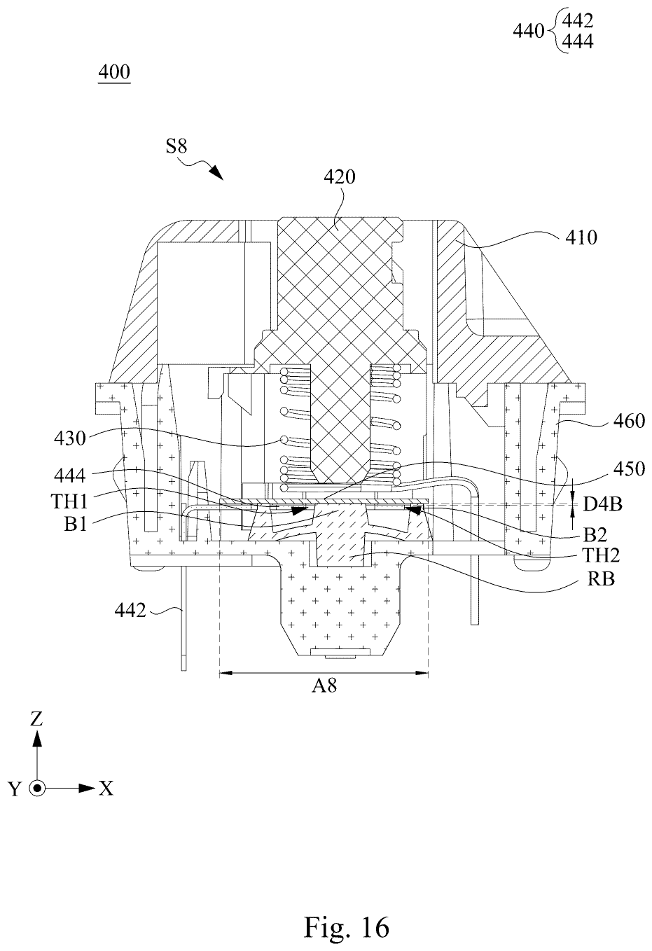

Reference is made to FIG. 16. FIG. 16 is a cross-sectional view of the capacitive switch device 400 in a pressed state S8 in accordance with an embodiment of the present disclosure. As shown in FIG. 16, in this embodiment, when the capacitive switch device 400 is in the pressed state S8, the sliding body 420 drives the second conductive part 450 along the third direction (for example, z-direction) by the elastic body 430 to move relative to the first conductive plate 444, so that when the flexible body RB abutted against by the second conductive part 450 abuts downward against the lower cover 460, there is a distance D4B between the first conductive plate 444 and the second conductive part 450. In some embodiments, the distance D4B in the pressed state S8 is less than the distance D4A in the unpressed state S7, and the distance D4A and the distance D4B must be non-zero distances (i.e., the first conductive part 440 and the second conductive part 450 are not in contact). As shown in FIG. 16, the first conductive plate 444 and the second conductive plate 354 have an overlapping area A8 in the first direction (e.g., x-direction).

In some other embodiments, the user may press the sliding body 420 excessively, causing the flexible body RB that is abutted downward against by the second conductive part 450 to be further compressed, so that the first conductive part 440 and the second conductive part 450 are in contact and cause the capacitive effect to fail. In this case, an insulating material may be coated on surfaces of the first conductive part 440 and the second conductive part 450. This ensures the capacitive effect between the first conductive part 440 and the second conductive part 450 can still be achieved as the sliding body 420 is over-pressed. It should be noted that the first conductive part 440 and the second conductive part 450 are “in contact with each other” if the insulating material and the first conductive part 440 are regarded as one and the insulating material and the second conductive part 450 are regarded as one as well.

Otherwise, the first conductive part 440 and the second conductive part 450 are separated by the insulating material and “do not in contact with each other” if the insulating material is regarded as an independent element from the first conductive part 440 and the second conductive part 450. Therefore, the two literal interpretations “the first conductive part 440 and the second conductive part 450 are in contact with each other” and “the first conductive part 440 and the second conductive part 450 are not in contact with each other” should be regarded as equivalent.

Reference is made to FIG. 13, FIG. 15, and FIG. 16. By the aforementioned structural configuration, when the capacitive switch device 400 continuously changes between the unpressed state S7 and the pressed state S8, the capacitive switch device 400 can generate the switch signal between the unpressed state S7 and the pressed state S8. In detail, when the capacitive switch device 400 is in the unpressed state S7, there is a relatively greater distance D4A between the first conductive plate 444 and the second conductive part 450, resulting in a relatively less capacitance. However, when the capacitive switch device 400 is in the pressed state S8, there is a relatively less distance D4B between the first conductive plate 444 and the second conductive part 450, resulting in a relatively greater capacitance. Since the capacitance value is negatively correlated with the distance, the capacitive switch device 400 can generate the switch signal related to the distance between the first conductive part 440 and the second conductive part 450.

Hereinafter, the structure and function of each component included in a capacitive switch device 500 of this embodiment and the connection relationship between the components will be described in detail.

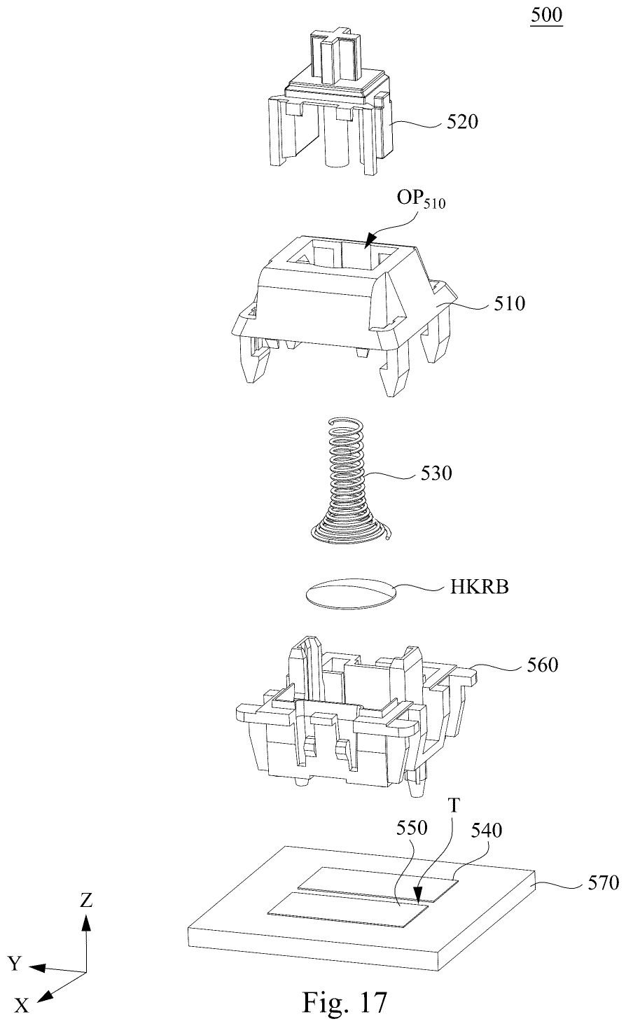

Reference is made to FIG. 17. FIG. 17 is an exploded view of a capacitive switch device 500 in accordance with an embodiment of the present disclosure. As shown in FIG. 17, in this embodiment, the capacitive switch device 500 includes an upper cover 510, a sliding body 520, an elastic body 530, a first conductive part 540, a second conductive part 550, a lower cover 560, and a circuit board 570. The upper cover 510, the sliding body 520, the elastic body 530, the lower cover 560, and the circuit board 570 are generally arranged in a top-down direction. In this embodiment, the upper cover 510 has an opening OP₅₁₀, and the sliding body 520 passes through the upper cover 510 by the opening OP₅₁₀. The elastic body 530 is located between the upper cover 510 and the lower cover 560.

As shown in FIG. 17, in this embodiment, the first conductive part 540 and the second conductive part 550 are disposed on the circuit board 570, and the first conductive part 540 is separated from the second conductive part 550. Specifically, the first conductive part 540 and the second conductive part 550 are not in contact, so that a capacitive effect can be generated between the first conductive part 540 and the second conductive part 550. As shown in FIG. 17, there is a trench T between the first conductive part 540 and the second conductive part 550.

In some embodiments, the materials of the upper cover 510, the sliding body 520, and the lower cover 560 may include, for example, plastic or other suitable insulating materials.

In some embodiments, the materials of the elastic body 530, the first conductive part 540, and the second conductive part 550 may include, for example, metal or other suitable conductive materials.

In some embodiments, the elastic body 530 may be, for example, a spring or other suitable elastic material. In some embodiments, the elastic body 530 may be, for example, a spiral spring or other suitable spring.

In some embodiments, the dielectric flexible body HKRB may be a dielectric material including, for example, a high dielectric constant material (a high-k material). In some embodiments, the dielectric flexure HKRB may be doped with, for example, barium titanate (BaTiO₃) or other suitable high-k materials.

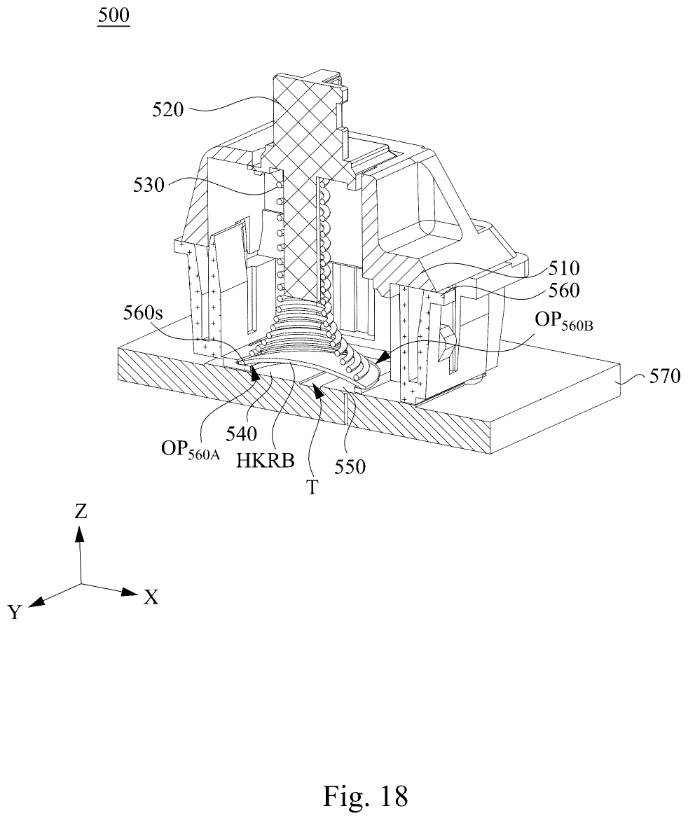

Reference is made to FIG. 18. FIG. 18 is a perspective cross-sectional view of the capacitive switch device 500 in accordance with an embodiment of the present disclosure. As shown in FIG. 18, in this embodiment, the lower cover 560 is disposed on the circuit board 570. The upper cover 510 is disposed on the lower cover 560. Specifically, the upper cover 510 is combined with the lower cover 560 (for example, locked with each other) and form an accommodating space. The sliding body 520 passes through the upper cover 510 and is configured to slide relative to the lower cover 560 along a third direction (e.g., z-direction). The elastic body 530 is located in the aforementioned accommodating space formed by the upper cover 510 and the lower cover 560. Two ends of the elastic body 530 respectively abut against the sliding body 520 and the lower cover 560. The sliding body 520 moves relative to the lower cover 560 by the elastic body 530. In some embodiments, the aforementioned dielectric flexible body HKRB is disposed on the lower cover 560 and is located between a bottom portion of the lower cover 560 and the elastic body 530.

As shown in FIG. 18, the lower cover 560 has an opening OP_{560A}, an opening OP_{560B}, and an abutting surface 560s. The opening OP_{560A} is located at the bottom portion of the lower cover 560, and the opening OP_{560A} exposes the trench T, the first conductive part 540, and the second conductive part 550. The opening OP_{560B} is located over the opening OP_{560A}, and the opening OP_{560B} communicates with the opening OP_{560A}. In some embodiments, opening OP_{560A}is located in a range of opening OP_{560B}. In some embodiments, a diameter of opening OP_{560B} is greater than a diameter of opening OP_{560A}. The abutting surface 560s is connected between the opening OP_{560A} and the opening OP_{560B}. As shown in FIG. 18, an edge of the dielectric flexible body HKRB abuts against the abutting surface 560s of the lower cover 560. As shown in FIG. 18, in some embodiments, the edge of the dielectric flexure HKRB conforms to a contour of the opening OP_{560B}.

The sliding body 520 drives the dielectric flexible body HKRB to move along the third direction (e.g., z-direction) relative to the first conductive part 540 and the second conductive part 550 to generate a switch signal corresponding to a capacitance value. The aforementioned capacitance value corresponds to a capacitance formed between the first conductive part 540 and the second conductive part 550.

How the capacitive switch device 500 generates the switch signal will be described in detail below.

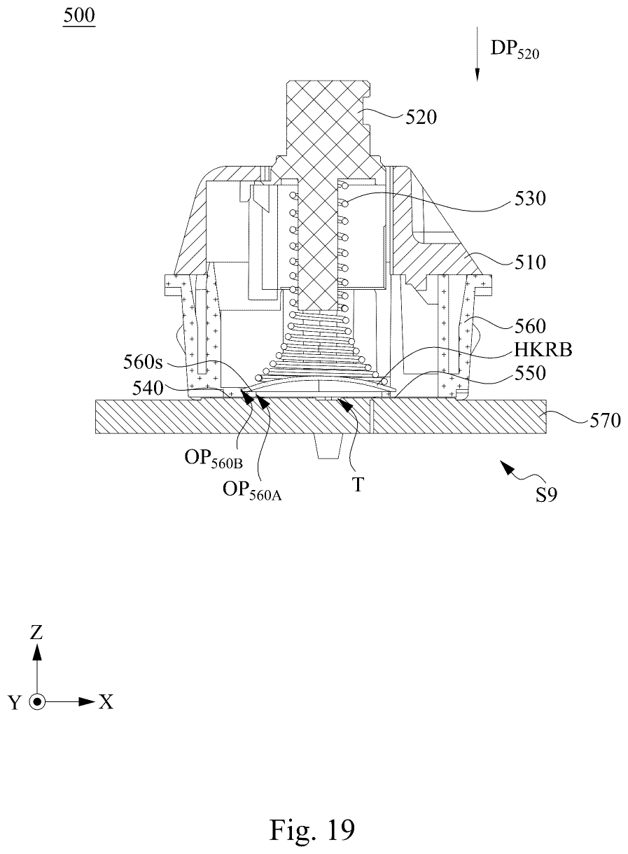

Reference is made to FIG. 19. FIG. 19 is a cross-sectional view of the capacitive switch device 500 in an unpressed state S9 in accordance with an embodiment of the present disclosure. As shown in FIG. 19, in this embodiment, the sliding body 520 of the capacitive switch device 500 is configured to allow the user to press along a pressing direction DP₅₂₀. When the capacitive switch device 500 is in the unpressed state S9, an end of the elastic body 530 abuts against the lower cover 560 by abutting against the dielectric flexible body HKRB. In detail, the end of the elastic body 530 abuts against the dielectric flexible body HKRB and then abuts against the abutting surface 560s of the lower cover 560. As shown in FIG. 19, when the capacitive switch device 500 is in the unpressed state S9, the center of the dielectric flexible body HKRB protrudes away from the circuit board 570, and the dielectric flexible body HKRB does not contact the first conductive part 540 and the second conductive part 550.

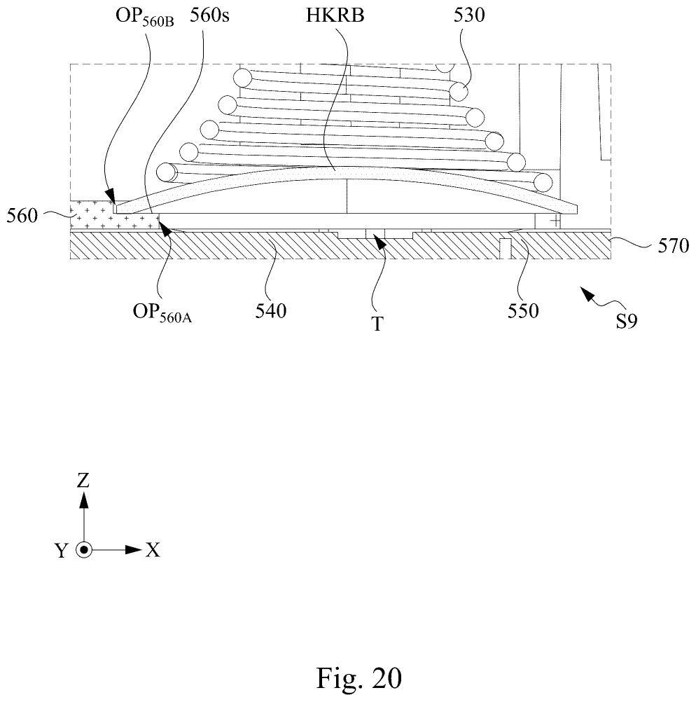

Reference is made to FIG. 20. FIG. 20 is a partial enlarged view of the capacitive switch device 500 in the unpressed state S9 of FIG. 19 in accordance with an embodiment of the present disclosure. Specifically, a variation of the capacitance formed between the first conductive part 540 and the second conductive part 550 is related to a variation of a dielectric constant of a medium between the first conductive part 540 and the second conductive part 550. In detail, when the dielectric constant of the medium between the first conductive part 540 and the second conductive part 550 remains constant, the capacitance formed between the first conductive part 540 and the second conductive part 550 also remains constant. When the dielectric constant of the medium between the first conductive part 540 and the second conductive part 550 increases, the capacitance formed between the first conductive part 540 and the second conductive part 550 will increase accordingly, thereby generating the switch signal. For example, when the capacitive switch device 500 is in the unpressed state S9, since the whole is in a stationary state, the capacitance formed between the first conductive part 540 and the second conductive part 550 remains constant.

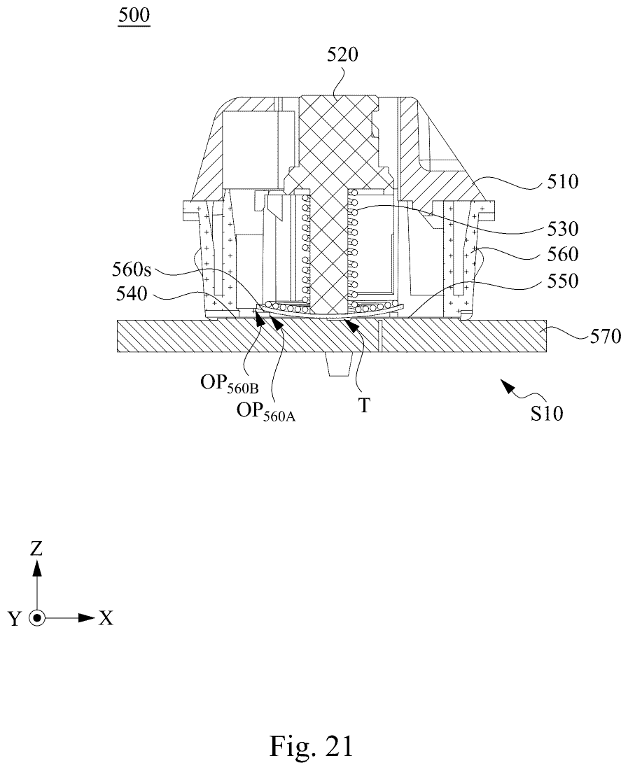

Reference is made to FIG. 21. FIG. 21 is a cross-sectional view of the capacitive switch device 500 in a pressed state S10 in accordance with an embodiment of the present disclosure. As shown in FIG. 21, in this embodiment, when the capacitive switch device 500 is in the pressed state S10, the sliding body 520 drives the dielectric flexible body HKRB along the third direction (for example, z-direction) by the elastic body 530 to move relative to the first conductive part 540 and the second conductive part 550. When the dielectric flexible body HKRB, which is abutted against by the elastic body 530, abuts downward against the lower cover 560 (i.e., from the unpressed state S9 to the pressed state S10), the elastic body 530 with multiple turns sequentially abut against the dielectric flexible body HKRB from the outermost turns to the inner turns, so that the center of the dielectric flexible body HKRB is gradually recessed toward the first conductive part 540 and the second conductive part 550.

In some other embodiments, the user may press the sliding body 520 excessively, so that the dielectric flexible body HKRB abutted downward against by the elastic body 530 is further pressed downward, so that a part of the dielectric flexible body HKRB falls in a range of the trench T.

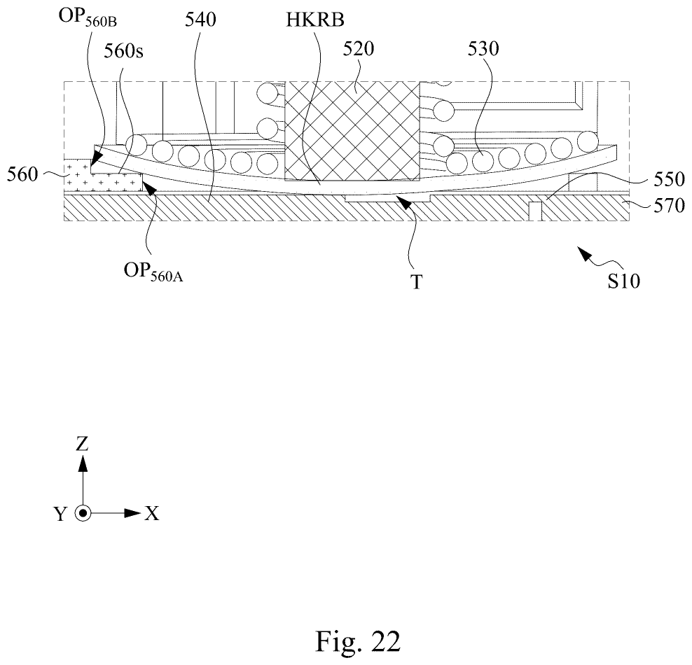

Reference is made to FIG. 22. FIG. 22 is a partial enlarged view of the capacitive switch device 500 in the pressed state S10 of FIG. 21 in accordance with an embodiment of the present disclosure. Specifically, as shown in FIG. 22, when the capacitive switch device 500 changes from the unpressed state S9 to the pressed state S10, the dielectric flexible body HKRB, which includes the high dielectric constant material for example, approaches the first conductive part 540 and the second conductive part 550, so that the dielectric constant of the medium between the first conductive part 540 and the second conductive part 550 increases, so the capacitance formed between the first conductive part 540 and the second conductive part 550 also increases accordingly, thereby generating the switch signal.

Reference is made to FIG. 17, FIG. 19, and FIG. 21. By the aforementioned structural configuration, when the capacitive switch device 500 continuously changes between the unpressed state S9 and the pressed state S10, the capacitive switch device 500 can generate the switch signal between the unpressed state S9 and the pressed state S10. In detail, when the capacitive switch device 500 is in the unpressed state S9, the dielectric flexible body HKRB is separated from the first conductive part 540 and the second conductive part 550 respectively. Therefore, the medium between the first conductive part 540 and the second conductive part 550 is mainly affected by air, thereby generating a relatively small capacitance. However, when the capacitive switch device 500 is in the pressed state S10, the dielectric flexible body HKRB approaches the first conductive part 540 and the second conductive part 550, so that the medium between the first conductive part 540 and the second conductive part 550 is further affected by the dielectric flexible body HKRB including high-k materials, thereby generating a relatively greater capacitance. Since the capacitance value is positively correlated to the dielectric constant, the capacitive switch device 500 can generate the switch signal related to the dielectric constant of the medium between the first conductive part 540 and the second conductive part 550.

Hereinafter, the structure and function of each component included in a capacitive switch device 600 of this embodiment and the connection relationship between the components will be described in detail.

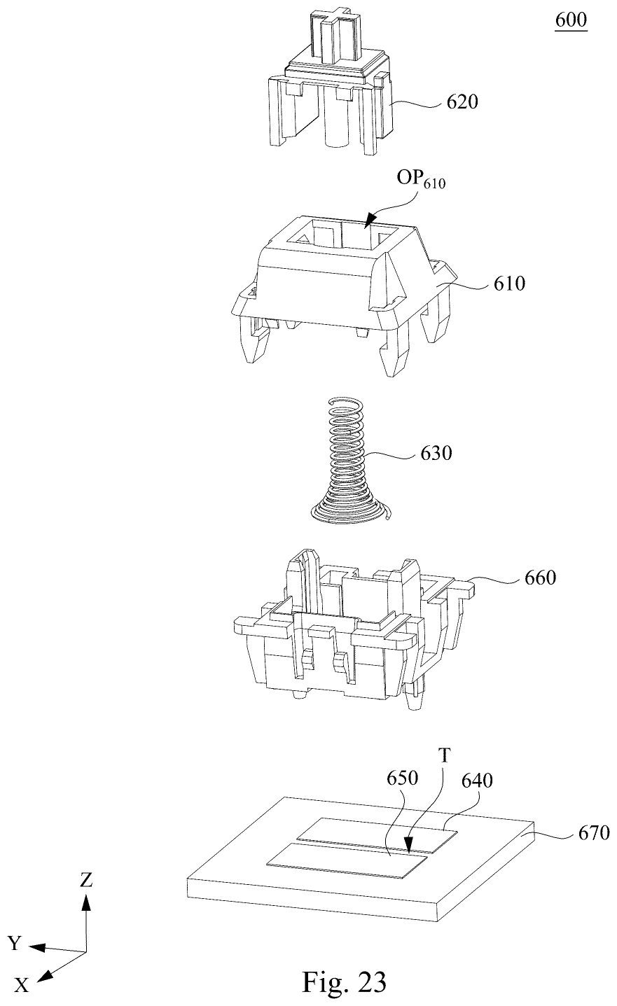

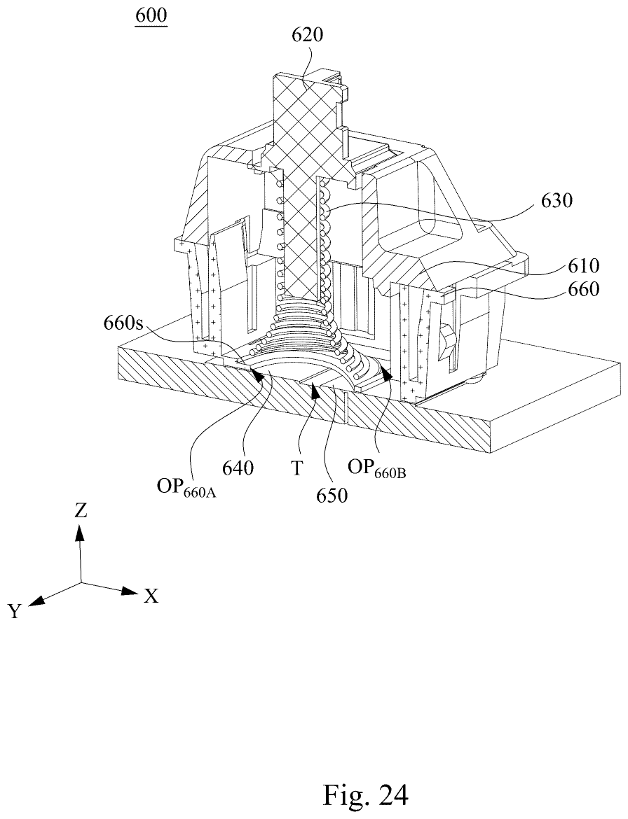

Reference is made to FIG. 23 and FIG. 24. FIG. 23 and FIG. 24 are respectively an exploded view and a perspective cross-sectional view of a capacitive switch device 600 in accordance with an embodiment of the present disclosure. As shown in FIG. 23 and FIG. 24, in this embodiment, the capacitive switch device 600 includes an upper cover 610, a sliding body 620, an elastic body 630, a first conductive part 640, a second conductive part 650, a lower cover 660, and the circuit board 670. The upper cover 610, the sliding body 620, the elastic body 630, the lower cover 660, and the circuit board 670 are generally arranged in a top-down direction. In this embodiment, the upper cover 610 has an opening OP₆₁₀, and the sliding body 620 passes through the upper cover 610 by the opening OP₆₁₀. The elastic body 630 is located between the upper cover 610 and the lower cover 660. As shown in FIG. 24, the lower cover 660 has an opening OP_{660A}, an opening OP_{660B}, and an abutting surface 660s. Since the structural configuration of the capacitive switch device 600 is substantially similar to the structural configuration of the capacitive switch device 500, the details will not be described again herein. The difference between the capacitive switch device 600 and the capacitive switch device 500 is that the capacitive switch device 600 does not include the dielectric flexible body HKRB.

How the capacitive switch device 600 generates the switch signal will be described in detail below.

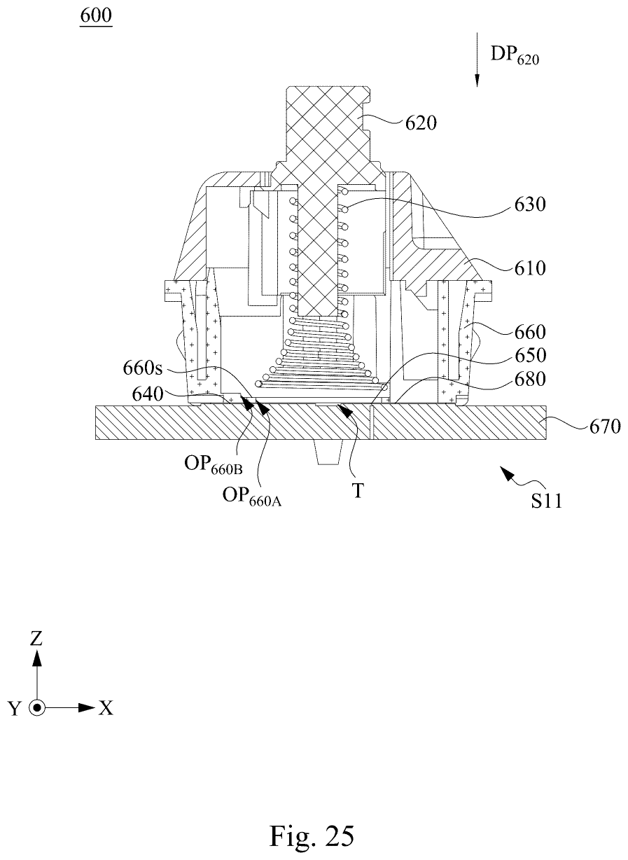

Reference is made to FIG. 25. FIG. 25 is a cross-sectional view of the capacitive switch device 600 in an unpressed state S11 in accordance with an embodiment of the present disclosure. As shown in FIG. 25, in this embodiment, the capacitive switch device 600 further includes an insulating layer 680. The insulating layer 680 covers at least the first conductive part 640 and the second conductive part 650. In some embodiments, the insulating layer 680 covers the entire surface of the circuit board 670 and fills the trench T. In some embodiments, the insulating layer 680 is located between the lower cover 660 and the circuit board 670. As shown in FIG. 25, in this embodiment, the sliding body 620 of the capacitive switch device 600 is configured to allow the user to press along a pressing direction DP₆₂₀. When the capacitive switch device 600 is in the unpressed state S11, an end of the elastic body 630 abuts against the lower cover 660. In detail, the end of the elastic body 630 abuts against the abutting surface 660s of the lower cover 660.

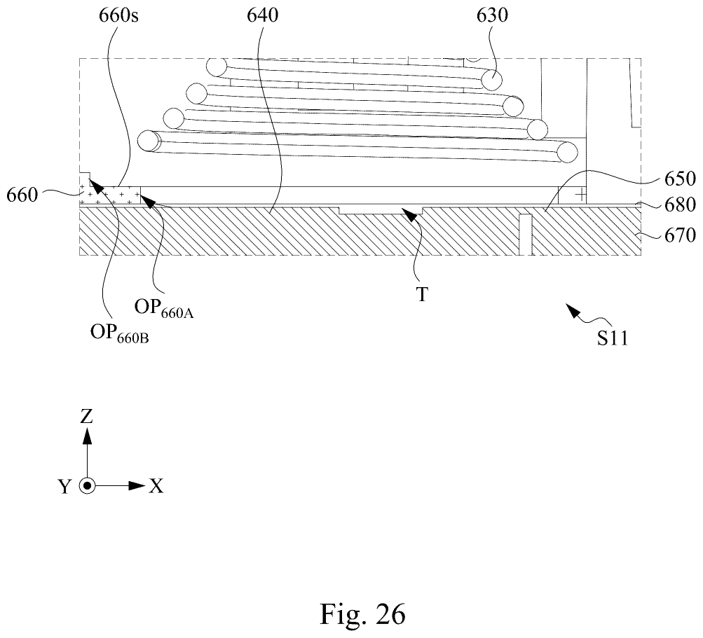

Reference is made to FIG. 26. FIG. 26 is a partial enlarged view of the capacitive switch device 600 in the unpressed state S11 of FIG. 25 in accordance with an embodiment of the present disclosure. Specifically, a variation of a capacitance formed between the first conductive part 640 and the second conductive part 650 is related to a variation of a dielectric constant of a medium between the first conductive part 640 and the second conductive part 650. For example, when the capacitive switch device 600 is in the unpressed state S11, since the whole is in a stationary state, the capacitance formed between the first conductive part 640 and the second conductive part 650 remains constant.

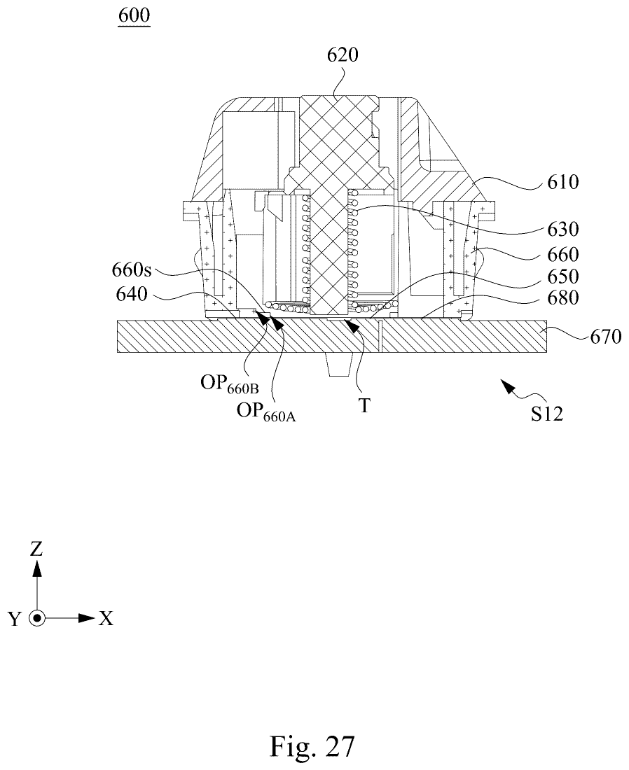

Reference is made to FIG. 27. FIG. 27 is a cross-sectional view of the capacitive switch device 600 in a pressed state S12 in accordance with an embodiment of the present disclosure. As shown in FIG. 27, in this embodiment, when the capacitive switch device 600 is in the pressed state S12, the sliding body 620 compresses the elastic body 630 along the third direction (e.g., z-direction). When the elastic body 630 is compressed (i.e., from the unpressed state S11 to the pressed state S12), the elastic body 630 is separated from the first conductive part 640 and the second conductive part 650 by the insulating layer 680, so that the elastic body 630 is not in direct contact with the first conductive part 640 and the second conductive part 650. When the elastic body 630 is compressed, the elastic body 630 with multiple turns sequentially abut against the abutting surface 660s and the circuit board 670 from the outermost turns to the inner turns.

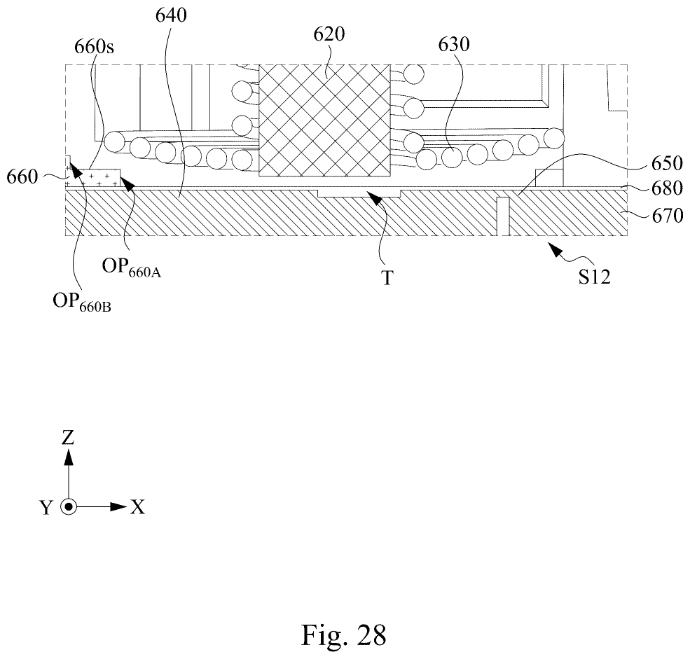

Reference is made to FIG. 28. FIG. 28 is a partial enlarged view of the capacitive switch device 600 in the pressed state S12 of FIG. 27 in accordance with an embodiment of the present disclosure. Specifically, as shown in FIG. 28, when the capacitive switch device 600 changes from the unpressed state S11 to the pressed state S12, since the multiple turns of the elastic body 630 approach the first conductive part 640 and the second conductive part 650, the dielectric constant of the medium between the first conductive part 640 and the second conductive part 650 increases, so that the capacitance formed between the first conductive part 640 and the second conductive part 650 also increases, thereby generating the switch signal.

Reference is made to FIG. 23, FIG. 25, and FIG. 27. By the aforementioned structural configuration, when the capacitive switch device 600 continuously changes between the unpressed state S11 and the pressed state S12, the capacitive switch device 600 can generate the switch signal between the unpressed state S11 and the pressed state S12. In detail, when the capacitive switch device 600 is in the unpressed state S11, the multiple turns of the elastic body 630 are respectively separated from the first conductive part 640 and the second conductive part 650. Therefore, the medium between the first conductive part 640 and the second conductive part 650 is mainly affected by air, thereby generating a relatively small capacitance. However, when the capacitive switch device 600 is in the pressed state S12, the multiple turns of the elastic body 630 approach the first conductive part 640 and the second conductive part 650, so that the medium between the first conductive part 640 and the second conductive part 650 is further affected by the multiple turns of the elastic body 630, thereby generating a relatively greater capacitance. Since the capacitance value is positively correlated to the dielectric constant, the capacitive switch device 600 can generate the switch signal related to the dielectric constant of the medium between the first conductive part 640 and the second conductive part 650.

From the above detailed description of the specific embodiments of the present disclosure, it can be clearly seen that in the capacitive switch device of the present disclosure, since the sliding body slides relative to the lower cover in a third direction by the elastic body, the user can repeatedly press the capacitive switch device serving as a keyboard key. In the capacitive switch device of the present disclosure, since the first conductive part is fixed on the circuit board and is static relative to the lower cover, and the second conductive part moves relative to the first conductive part as the sliding body slides, so that a capacitance will be generated between the second conductive part and the first conductive part when the second conductive part moves relative to the first conductive part. In the capacitive switch device of the present disclosure, when the second conductive part moves relative to the first conductive part, the capacitance value between the second conductive part and the first conductive part will alter with the change of the overlapping area between the second conductive part and the first conductive part and the change of the distance between the second conductive part and the first conductive part, so that when the user presses the capacitive switch device, the switch signal related to the overlapping area of the second conductive part and the first conductive part or the distance between the second conductive part and the first conductive part can be generated. In the capacitive switch device of the present disclosure, when the first conductive part and the second conductive part are fixed on the circuit board, the user can control the dielectric constant of a medium between the first conductive part and the second conductive part to generate a variation of the capacitance, so that when the user presses the capacitive switch device, the switch signal related to the dielectric constant of the medium between the first conductive part and the second conductive part can be generated. Accordingly, the capacitive switch device of the present disclosure can generate switch signals between the pressed state and the unpressed state, compared with the traditional mechanical switch that can only generate all-or-nothing switch signals between the pressed state and the unpressed state, thereby increasing the flexibility and possibilities of keyboard keys in the field of e-sports.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A capacitive switch device, comprising:
a lower cover disposed on a circuit board;
an upper cover disposed on the lower cover;
a sliding body passing through the upper cover and configured to slide relative to the lower cover along a first direction;
an elastic body located between the lower cover and the upper cover, and two ends of the elastic body respectively abutting against the sliding body and the lower cover;
a first conductive part disposed on the circuit board and being static relative to the lower cover; and
a second conductive part connected to the sliding body and moving relative to the first conductive part,
wherein the sliding body drives the second conductive part to move along the first direction to generate a switch signal corresponding to a capacitance between the first conductive part and the second conductive part, and the switch signal is related to an overlapping area of the first conductive part and the second conductive part in a second direction.

2. The capacitive switch device of claim 1, wherein the first conductive part further comprises a first fixed plate disposed on the circuit board, a first conductive narrow plate bent from the first fixed plate, and a first conductive wide plate parallelly extended from the first conductive narrow plate, and the second conductive part further comprises a second fixed plate connected to the sliding body and a second conductive plate vertically extended from the second fixed plate, wherein the overlapping area of the first conductive part and the second conductive part in the second direction is defined by the first conductive narrow plate, the first conductive wide plate, and the second conductive plate.

3. The capacitive switch device of claim 2, wherein a non-zero distance is between the first conductive narrow plate and the second conductive plate and between the first conductive wide plate and the second conductive plate.

4. The capacitive switch device of claim 1, wherein the first conductive part further comprises a first fixed plate passing through the lower cover and two first conductive sub-plates connected to the first fixed plate, and the second conductive part further comprises a second fixed plate connected to the sliding body and two second conductive sub-plates connected to the second fixed plate, wherein the overlapping area of the first conductive part and the second conductive part in the second direction is defined by the two first conductive sub-plates and the two second conductive sub-plates.

5. The capacitive switch device of claim 4, wherein one of the two first conductive sub-plates is located between the two second conductive sub-plates, and one of the two second conductive sub-plates is located between the two first conductive sub-plates.

6. A capacitive switch device, comprising:
a lower cover disposed on a circuit board;
an upper cover disposed on the lower cover;
a sliding body passing through the upper cover and configured to slide relative to the lower cover along a first direction;
an elastic body located between the lower cover and the upper cover, and two ends of the elastic body respectively abutting against the sliding body and the lower cover;
a first conductive part disposed on the circuit board and being static relative to the lower cover; and
a second conductive part connected to the elastic body and moving relative to the first conductive part,
wherein the sliding body drives the second conductive part to move by the elastic body to generate a switch signal corresponding to a capacitance between the first conductive part and the second conductive part, and the switch signal is related to a distance between the first conductive part and the second conductive part in a second direction.

7. The capacitive switch device of claim 6, wherein the first conductive part further comprises a first fixed plate disposed on the circuit board and a first conductive plate parallelly extended from the first fixed plate, and the second conductive part further comprises a second swinging plate abutted against by the elastic body and a second conductive plate bent from the second swinging plate.

8. The capacitive switch device of claim 7, further comprising a spacer located between the first conductive plate and the second conductive plate and disposed on the second conductive plate, and the first conductive plate being separated from the second conductive plate by a non-zero distance by the spacer.

9. The capacitive switch device of claim 7, wherein the second swinging plate is abutted against by the elastic body and swings when the sliding body drives the second conductive part to move by the elastic body, so that the second conductive plate moves toward the first conductive plate.

10. The capacitive switch device of claim 6, further comprising a flexible body located between the first conductive part and the second conductive part, and the flexible body abuts against the second conductive part so that a non-zero distance is between the second conductive part and the first conductive part, wherein the second conductive part is located over the first conductive part, the flexible body passes through the first conductive part, and the first direction is parallel to the second conductive part.

11. A capacitive switch device, comprising:
a lower cover disposed on a circuit board;
an upper cover disposed on the lower cover;
a sliding body passing through the upper cover and configured to slide relative to the lower cover along a first direction;
an elastic body located between the lower cover and the upper cover, and two ends of the elastic body respectively abutting against the sliding body and the lower cover;
a first conductive part disposed on the circuit board and being static relative to the lower cover; and
a second conductive part disposed on the circuit board and separated from the first conductive part,
wherein the sliding body drives the elastic body to elastically stretch and compress along the first direction to generate a switch signal corresponding to a capacitance between the first conductive part and the second conductive part, and the switch signal is related to a dielectric constant between the first conductive part and the second conductive part.

12. The capacitive switch device of claim 11, wherein a trench is between the first conductive part and the second conductive part, and the first conductive part is separated from the second conductive part by the trench.

13. The capacitive switch device of claim 12, further comprising an insulating layer covering the first conductive part and the second conductive part, and the elastic body being separated from the first conductive part and the second conductive part by the insulating layer when the elastic body is compressed.

14. The capacitive switch device of claim 12, further comprising a dielectric flexible body disposed on the lower cover, the lower cover having a first opening exposing the trench, the first conductive part, and the second conductive part and being located on a bottom portion of the lower cover and a second opening located over the first opening and communicating with the first opening, and the first opening being located in a range of the second opening.

15. The capacitive switch device of claim 14, wherein the lower cover has an abutting surface connected between the first opening and the second opening, and an edge of the dielectric flexible body abuts against the abutting surface.

16. The capacitive switch device of claim 14, wherein an end of the elastic body abuts against the lower cover by abutting against the dielectric flexible body.

17. The capacitive switch device of claim 14, wherein the dielectric flexible body comprises a material with high dielectric constant.

18. The capacitive switch device of claim 14, wherein the elastic body is separated from the first conductive part and the second conductive part by the dielectric flexible body when the elastic body is compressed and approaches the first conductive part and the second conductive part.
